(19) United States
(12) Patent Application Publication
(10) Pub. No.: US 2019/0305178 A1
(43) Pub. Date: Oct. 3, 2019

(54) SYSTEM HAVING TRANSFER HEAD FOR TRANSFERRING MICRO LED

(71) Applicant: POINT ENGINEERING CO., LTD., Asan (KR)

(72) Inventors: Bum Mo Ahn, Suwon (KR); Seung Ho Park, Hwaseong (KR); Sung Hyun Byun, Hwaseong (KR)

(21) Appl. No.: 16/370,674

(22) Filed: Mar. 29, 2019

(30) Foreign Application Priority Data
Mar. 30, 2018 (KR) 10-2018-0036959

(51) Int. Cl. H01L 33/00; H01L 33/20; H01L 21/02

(52) U.S. Cl. CPC H01L 33/0095; H01L 21/02282; H01L 33/20

(57) ABSTRACT

The present invention relates to a system having a transfer head for transferring a micro light-emitting diode (micro LED) from a first substrate to a second substrate. More particularly, the present invention relates to a system having a transfer head for transferring a micro LED, the system being configured such that the transfer head does not use an electrostatic force and preventing the generation of an electrostatic force which may cause a problem. In addition, the present invention relates to a system having a transfer head for transferring a micro LED, the system employing a suction structure using a suction force to transfer a micro LED by a porous member, thereby solving problems of the related art.

### CROSS REFERENCE TO RELATED APPLICATION

The present application claims priority to Korean Patent Application No. 10-2018-0036959, filed Mar. 30, 2018, the entire contents of which is incorporated herein for all purposes by this reference.

### BACKGROUND OF THE INVENTION

### Field of the Invention

The present invention relates to a system having a transfer head for transferring a micro light-emitting diode (micro LED) from a first substrate to a second substrate.

### Description of the Related Art

Currently, the display market is still dominated by LCDs, but OLEDs are quickly replacing LCDs and emerging as mainstream products. In a current situation where display makers are rushing to participate in the OLED market, micro light-emitting diode (hereinafter, referred to as micro LED) displays have emerged as another next generation display. Liquid crystal and organic materials are the core materials of LCDs and OLEDs, respectively, whereas the micro LED display uses 1 μm to 100 μm of an LED chip itself as light emitting material.

Since the term “micro LED” emerged in a patent “MICRO-LED ARRAYS WITH ENHANCED LIGHT EXTRACTION” in 1999 (Korean Patent No. 10-0731673, hereinafter referred to as ‘Related Art 1’) disclosed by Cree Inc., related research papers based thereon were subsequently published. In order to apply the micro LED to a display, it is necessary to develop a customized microchip based on a flexible material and/or flexible device using a micro LED device, and techniques of transferring the micrometer-sized LED chip and mounting the LED chip on a display pixel electrode are required.

Particularly, with regard to the transfer of the micro LED device to a display substrate, as the LED size is reduced to 1 μm to 100 μm, it is impossible to use a conventional pick-and-place machine, and a technology of a transfer head for higher precision is required.

Luxvue Technology Corp., USA, proposed a method of transferring a micro LED using an electrostatic head (Korean Patent Application Publication No. 10-2014-0112486, hereinafter referred to as ‘Related Art 2’). A transfer principle of the Related Art 2 is that a voltage is applied to a head portion made of a silicone material so that the head portion comes into close contact with a micro LED due to electrification. However, this method may cause damage to micro LEDs due to electrification caused by the voltage applied to the head portion during induction of static electricity.

In addition, even when micro LEDs are gripped by a method different from the Related Art 2 (for example, a grip force by vacuum, etc.), an undesirable electrostatic force may be generated between the micro LEDs and the transfer head.

The electrostatic force not only damages the micro LED but also causes the micro LED to stick to the transfer head when unloading the micro LEDs from the transfer head, whereby positional error occurs when unloading the micro LED or unloading of the micro LEDs is not performed at all.

In order to solve the problems of the related art described above, it is necessary to solve the above-mentioned problems while adopting the basic principles adopted in the related art. However, there is a limit to solving the problems because such problems are derived from the basic principles adopted in the related art. Therefore, applicants of the present invention have not only solved the problems of the related art but also proposed an advanced method which has not been considered in the related art.

### DOCUMENTS OF RELATED ART

(Patent Document 1) Korean Patent No. 10-0731673; and

(Patent Document 2) Korean Patent Application Publication No. 10-2014-0112486

### SUMMARY OF THE INVENTION

Accordingly, the present invention has been made keeping in mind the above problems occurring in the related art, and an objective of the present invention is to provide a system having a transfer head for transferring a micro LED, the system being configured such that the transfer head does not use an electrostatic force and preventing the generation of an electrostatic force which may cause a problem.

In addition, another objective of the present invention is to provide a system having a transfer head for transferring a micro LED, the system employing a suction structure using a suction force to transfer a micro LED by a porous member, thereby solving problems of the related art.

In order to achieve the above objective, there is provided a system having a transfer head for transferring a micro LED, the system including: a first substrate provided in a transfer chamber and on which a micro LED is formed; a second substrate provided in the transfer chamber and on which the micro LED is mounted; a transfer head provided between the first substrate and the second substrate in the transfer chamber and transferring the micro LED; and a spraying unit provided in the transfer chamber spraying ionized gas.

In addition, the spraying unit may be configured as a spraying unit for a transfer chamber to replace the atmosphere in the transfer chamber with the ionized gas.

In addition, the spraying unit may be configured as a spraying unit for the first substrate to spray the ionized gas on an upper surface of the first substrate.

In addition, the spraying unit may be configured as a spraying unit for the second substrate to spray the ionized gas on an upper surface of the second substrate.

In addition, the spraying unit may be configured as a spraying unit for the transfer head to spray the ionized gas on a lower surface of the micro LED gripped by the transfer head.

As described above, a system having a transfer head for transferring a micro LED according to the present invention has the following effects.

According to the present invention, it is possible to prevent the generation of an electrostatic force by employing a spraying unit, whereby it is possible to prevent positional error when unloading a micro LED or to prevent the micro LED from sticking to a transfer head, which may cause unloading thereof to not be performed at all.

In addition, it is possible for a transfer head to easily transfer a micro LED from a first substrate to a second substrate by a porous member.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a view illustrating a system for transferring a micro LED according to a first embodiment of the present invention;

FIG. 2 is a view illustrating micro LEDs formed on a first substrate of FIG. 1;

FIG. 3 is a view illustrating micro LEDs mounted on a second substrate of FIG. 1;

FIG. 4 is a view illustrating a state in which a transfer head of FIG. 1 grips micro LEDs;

FIGS. 5A to 5D are views illustrating examples of a grip area and a non-grip area of the transfer head of FIG. 4;

FIGS. 6A to 6D are views illustrating a method of transferring micro LEDs using the transfer head of FIG. 4;

FIG. 7 is a view illustrating a system for transferring a micro LED according to a second embodiment of the present invention;

FIG. 8 is a view illustrating a first modification of the transfer head according to the present invention;

FIG. 9 is an enlarged view of a portion ‘A’ of FIG. 8;

FIG. 10 is a view illustrating a state in which the transfer head of FIG. 8 grips micro LEDs;

FIG. 11 is a view illustrating a state in which a second modification of the transfer head grips micro LEDs;

FIG. 12 is a view illustrating a state in which a third modification of the transfer head grips micro LEDs;

FIG. 13 is a view illustrating a state in which a fourth modification of the transfer head grips micro LEDs;

FIG. 14 is a view illustrating a state in which a fifth modification of the transfer head grips micro LEDs;

FIGS. 15 and 16 are views illustrating a state in which a sixth modification of the transfer head grips micro LEDs;

FIG. 17 is a view illustrating a state in which a seventh modification of the transfer head grips micro LEDs;

FIG. 18 is a view illustrating a state in which an eighth modification of the transfer head grips micro LEDs;

FIG. 19 is a view illustrating a state in which a ninth modification of the transfer head grips micro LEDs;

FIG. 20 is a view illustrating a state in which a tenth modification of the transfer head grips micro LEDs;

FIG. 21 is a view illustrating various embodiments of a dam of the transfer head of FIG. 20;

FIG. 22 is a view illustrating a state in which an eleventh modification of the transfer head grips micro LEDs;

FIG. 23 is a view illustrating a state in which a twelfth modification of the transfer head grips micro LEDs; and

FIG. 24 is a view illustrating a state in which a thirteenth modification of the transfer head grips micro LEDs.

### DETAILED DESCRIPTION OF THE INVENTION

Contents of the description below merely exemplify the principle of the invention. Therefore, those of ordinary skill in the art may implement the theory of the invention and invent various apparatuses which are included within the concept and the scope of the invention even though it is not clearly explained or illustrated in the description. Furthermore, in principle, all the conditional terms and embodiments listed in this description are clearly intended for the purpose of understanding the concept of the invention, and one should understand that this invention is not limited to the exemplary embodiments and the conditions.

The above described objectives, features, and advantages will be more apparent through the following detailed description related to the accompanying drawings, and thus those of ordinary skill in the art may easily implement the technical spirit of the invention.

The embodiments of the present invention are described with reference to cross-sectional views and/or perspective views which schematically illustrate ideal embodiments of the present invention. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of multiple micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

System 10 for Transferring a Micro LED According to a First Embodiment of the Present Invention

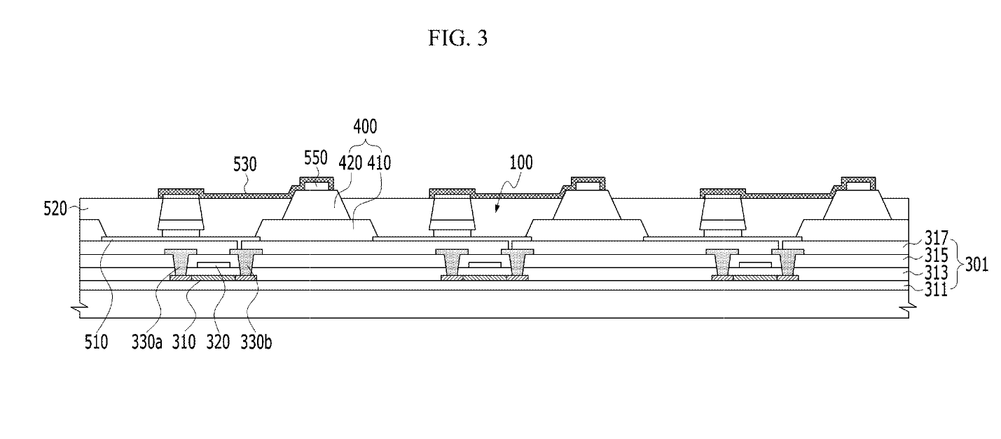

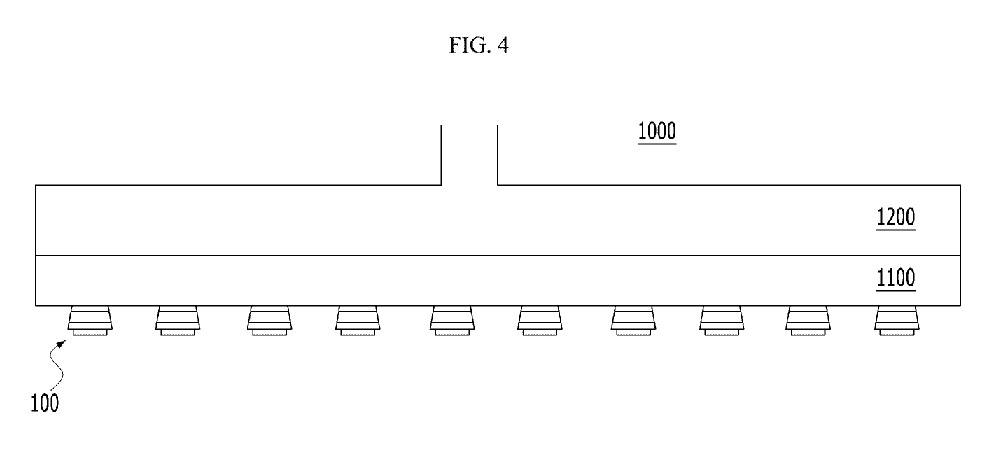

Hereinbelow, a system 10 for transferring a micro LED according to a first embodiment of the present invention will be described with reference to FIGS. 3 and 4.

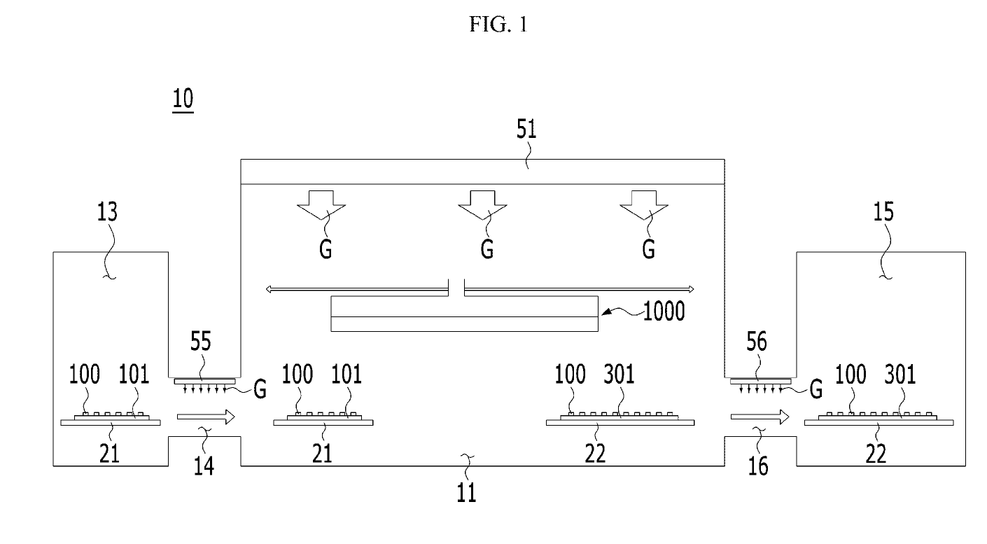

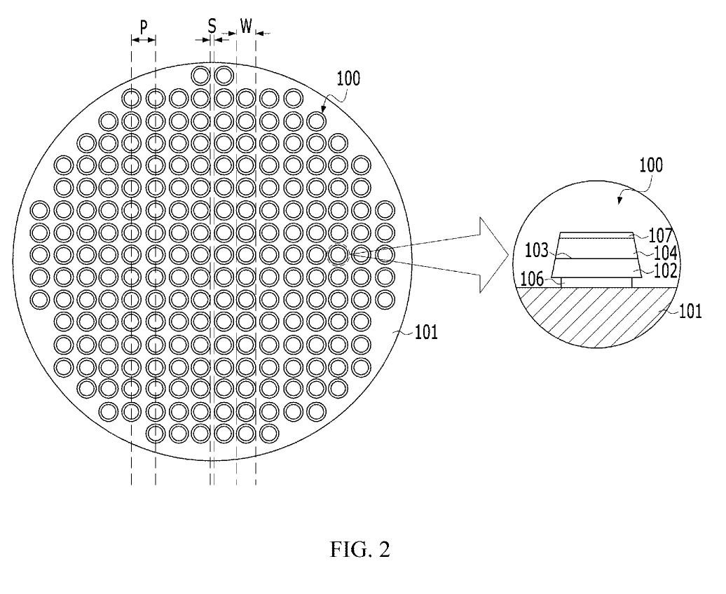

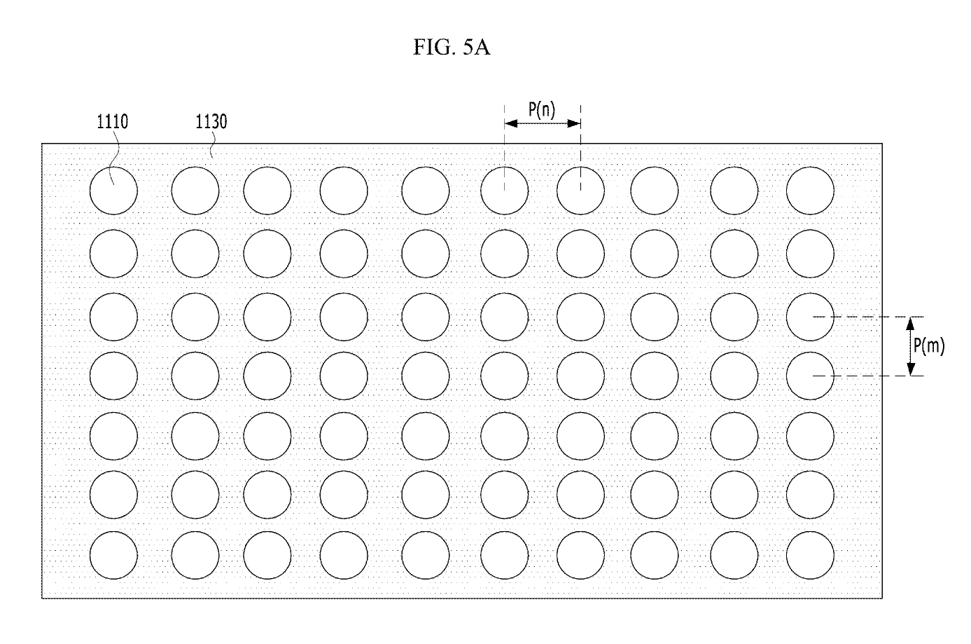

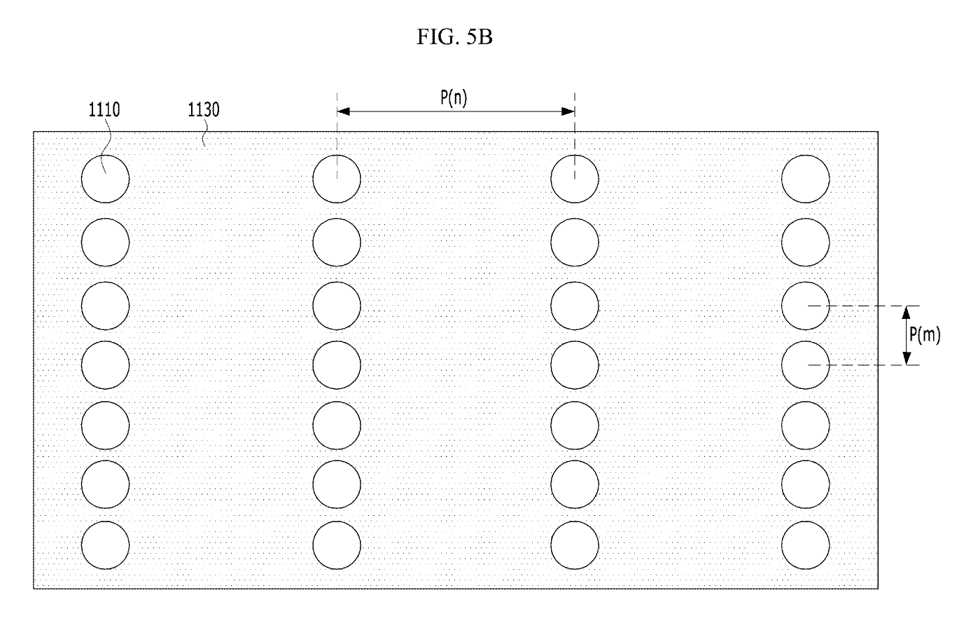

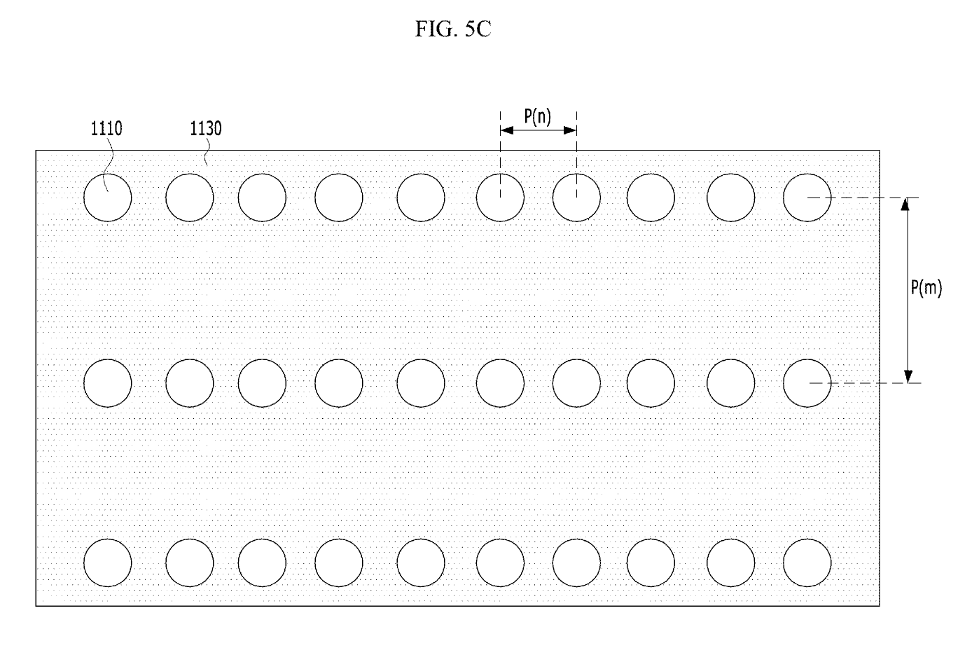

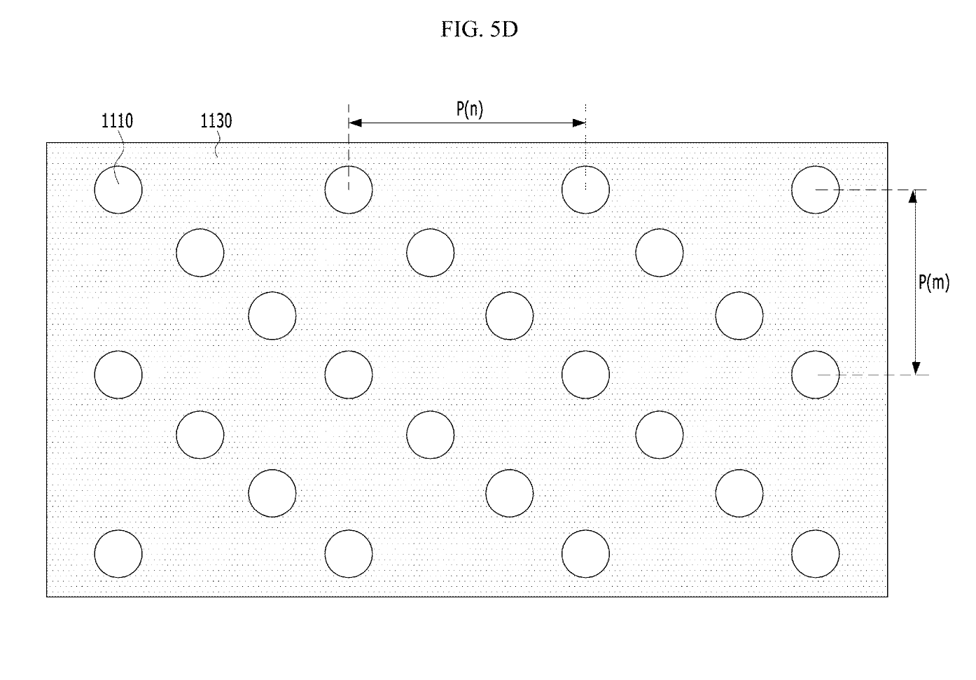

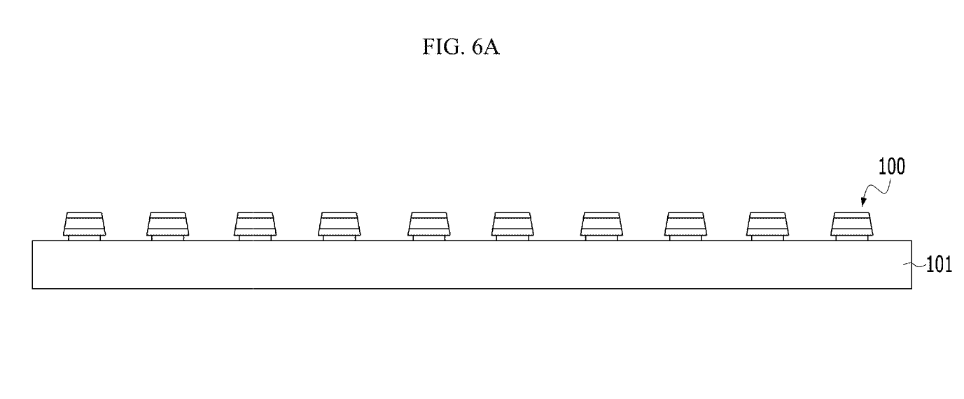

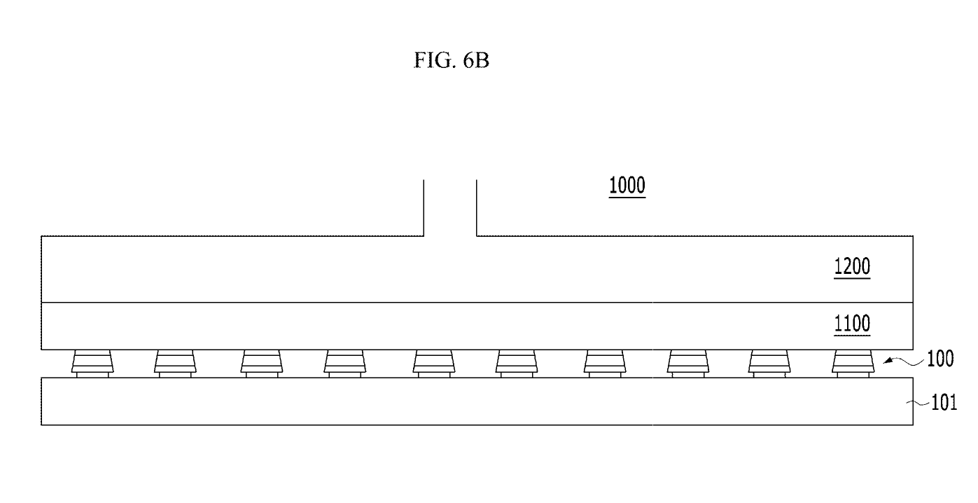

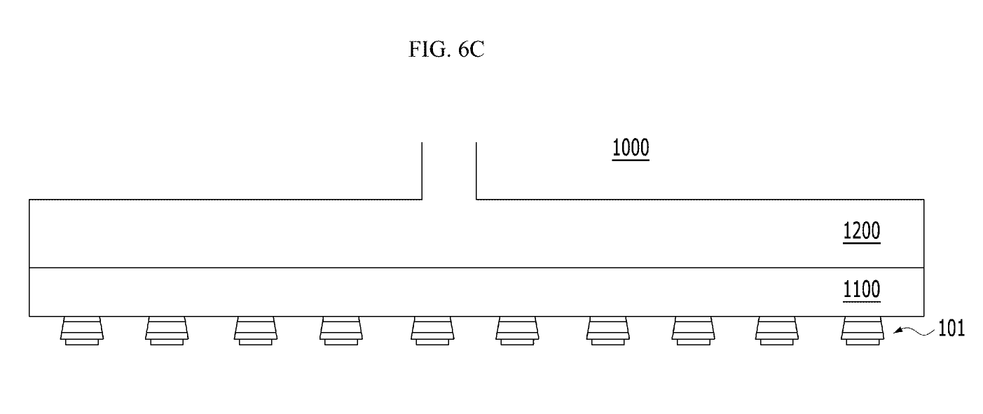

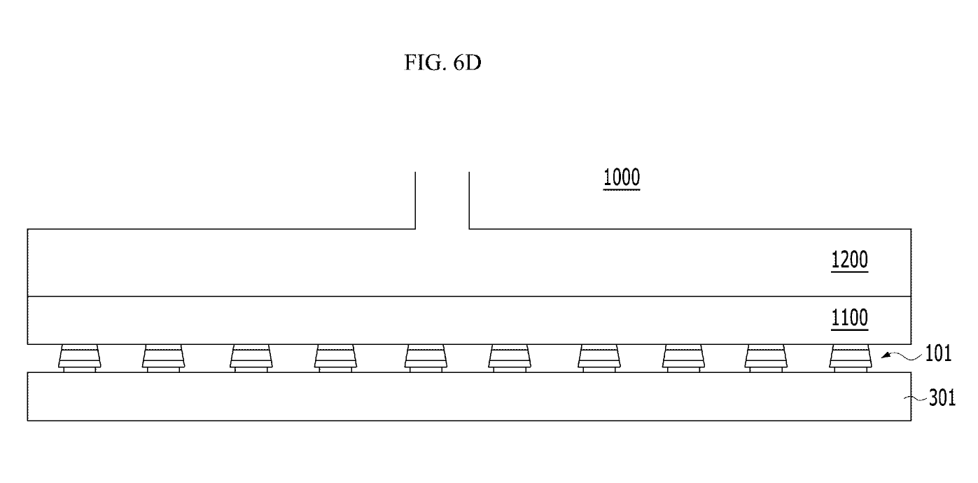

FIG. 1 is a view illustrating a system for transferring a micro LED according to a first embodiment of the present invention; FIG. 2 is a view illustrating micro LEDs formed on a first substrate of FIG. 1; FIG. 3 is a view illustrating micro LEDs mounted on a second substrate of FIG. 1; FIG. 4 is a view illustrating a state in which a transfer head of FIG. 1 grips micro LEDs; FIGS. 5A to 5D are views illustrating examples of a grip area and a non-grip area of the transfer head of FIG. 4; and FIGS. 6A to 6D are views illustrating a method of transferring micro LEDs using the transfer head of FIG. 4.

Referring to FIG. 1, a system 10 for transferring a micro LED according to the first embodiment of the present invention includes: a transfer chamber 11 in which micro LEDs 100 are transferred; a loading chamber 13 communicating with the transfer chamber 11 and providing a space for transferring a first substrate 101 to the transfer chamber 11; and an unloading chamber 15 communicating with the transfer chamber 11 and providing a space for transferring a second substrate 301 whose transfer is completed in the transfer chamber 11.

The loading chamber 13 communicates with the transfer chamber 11 through a first passage 14. In addition, the loading chamber 13 receives the first substrate 101 from an external process chamber and functions to provide a space for transferring the first substrate 101 to the transfer chamber 11 in order to perform a transfer process in which the micro LEDs 100 formed on the first substrate 101 are mounted on the second substrate 301.

A first base 21 transfers the first substrate 101 from the loading chamber 13 to the transfer chamber 11.

The first substrate 101 is seated on the first base 21, and the first base 21 is provided to be movable between the loading chamber 13 and the transfer chamber 11 through the first passage 14 along the X-axis. Therefore, as the first base 101 moves from the loading chamber 13 to the transfer chamber 11, the first substrate 101 seated on the first base 21 is transferred from the loading chamber 13 to the transfer chamber 11.

The unloading chamber 15 communicates with the transfer chamber 11 through a second passage 16. In addition, the unloading chamber 15 functions to provide a space for transferring the second substrate 301 on which the micro LEDs 100 are mounted after the transfer process is completed to the external process chamber.

A second base 22 transfers the second substrate 301 from the transfer chamber 11 to the unloading chamber 15.

The second substrate 301 is seated on the second base 22, and the second base 22 is provided to be movable between the transfer chamber 11 and the unloading chamber 15 through the second passage 16 along the X-axis. Therefore, as the second base 22 moves from the transfer chamber 11 to the unloading chamber 15, the second substrate 301 seated on the second base 22 is transferred from the transfer chamber 11 to the unloading chamber 15.

The transfer chamber 11 is disposed between the loading chamber 13 and the unloading chamber 15 and functions to provide a space where the micro LEDs 100 are transferred by a transfer head 1000. In this case, the transfer chamber 11 communicates with the loading chamber 13 and the unloading chamber 15 through the first passage 14 and the second passage 16, respectively.

The transfer chamber 11 includes: the first substrate 101 disposed in the transfer chamber 11 and on which the micro LEDs 100 are formed; the second substrate 301 disposed in the transfer chamber 11 and on which the micro LEDs 100 are mounted; the transfer head 1000 provided between the first substrate 101 and the second substrate 301 in the transfer chamber 11 to transfer the micro LEDs 100; and a spraying unit spraying ionized gas G.

The first substrate 101 is seated on the top of the first base 21 to be disposed in the transfer chamber 11, and the second substrate 301 is seated on the top of the second base 22 to be disposed in the transfer chamber 11.

Hereinbelow, the micro LEDs 100 transferred by the transfer head 1000 and the first substrate 101 on which the micro LEDs 100 are formed will be described.

As illustrated in FIG. 2, the micro LEDs 100 are fabricated and positioned on the first substrate 101. In other words, the micro LEDs 100 are formed on the first substrate 101.

The first substrate 101 may be formed into a conductive substrate or an insulating substrate. For example, the first substrate 101 is formed of at least one selected from among the group consisting of sapphire, SiC, Si, GaAs, GaN, ZnO, GaP, InP, Ge, and Ga₂O₃.

Each of the micro LEDs 100 includes: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be a semiconductor material having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, and the like, and the layer may be doped with a p-type dopant such as Mg, Zn, Ca, Sr, and Ba.

The second semiconductor layer 104 may be implemented, for example, as an n-type semiconductor layer. An n-type semiconductor layer may be a semiconductor material having a composition formula of InₓAl_{y}Ga_{1-x-y}N (0≤x≤1, 0≤y≤1, 0≤x+y≤1), for example, GaN, AlN, AlGaN, InGaN, InNInAlGaN, AlInN, and the like, and the layer may be doped with an n-type dopant such as Si, Ge, and Sn.

However, the present invention is not limited to this. The first semiconductor layer 102 may include an n-type semiconductor layer, and the second semiconductor layer 104 may include a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be formed of a semiconductor material having a composition formula of InₓAl_{y}Ga_{1-x-y}N (0≤x≤1, 0≤y≤1, 0≤x+y≤1) and may have a single quantum well structure or a multi quantum well (MQW) structure. In addition, the active layer 103 may have a quantum wire structure or a quantum dot structure.

The first semiconductor layer 102 may be provided with the first contact electrode 106, and the second semiconductor layer 104 may be provided with the second contact electrode 107. The first contact electrode 106 and/or the second contact electrode 107 may include one or more layers and may be formed of various conductive materials including a metal, conductive oxide, and conductive polymer.

The multiple micro LEDs 100 formed on the first substrate 101 are separated into individual pieces by cutting along a cutting line using a laser or the like or by etching. Then, it is possible to separate the individual micro LEDs 100 from the first substrate 101 by a laser lift-off process.

In FIG. 1, the letter ‘P’ denotes a pitch distance between the micro LEDs 100, ‘S’ denotes a separation distance between the micro LEDs 100, and ‘W’ denotes a width of each micro LED 100.

Hereinbelow, the second substrate 301 on which the micro LEDs 100 are mounted will be described.

When the micro LEDs 100 are transferred to and mounted on the second substrate 301 by the transfer head 1000, the second substrate 301 is configured into a micro LED structure having the micro LEDs 100 as illustrated in FIG. 3.

The second substrate 301 may include various materials. For example, the second substrate 301 may be made of a transparent glass material having SiO₂ as a main component. However, materials of the second substrate 301 are not limited to this, and the second substrate 301 may be made of a transparent plastic material and have solubility. The plastic material may be an organic insulating substance selected from the group consisting of polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In the case of a bottom emission type in which an image is implemented in a direction of the second substrate 301, the second substrate 301 is required to be formed of a transparent material. However, in the case of a top emission type in which an image is implemented in a direction opposite to the second substrate 301, the second substrate 301 is not required to be formed of a transparent material. In this case, the second substrate 301 may be formed of metal.

In the case of forming the second substrate 301 using metal, the second substrate 301 may be formed of at least one metal selected from among the group consisting of iron, chromium, manganese, nickel, titanium, molybdenum, stainless steel (SUS), Invar, Inconel, and Kovar, but is not limited thereto.

The second substrate 301 may include a buffer layer 311. The buffer layer 311 provides a flat surface and blocks foreign matter or moisture from penetrating therethrough. For example, the buffer layer 311 may be formed of an inorganic substance such as silicon oxide, silicon nitride, silicon oxynitride, aluminum oxide, aluminum nitride, titanium oxide, and titanium nitride, or an organic substance such as polyimide, polyester, and acrylic. Alternatively, the buffer layer 311 may be formed in a stacked manner with the exemplified substances.

A thin-film transistor (TFT) may include an active layer 310, a gate electrode 320, a source electrode 330a, and a drain electrode 330b.

Hereinafter, a case where a TFT is a top gate type in which the active layer 310, the gate electrode 320, the source electrode 330a, and the drain electrode 330b are sequentially formed will be described. However, the present embodiment is not limited thereto, and various types of TFTs such as a bottom gate TFT may be employed.

The active layer 310 may contain a semiconductor material, such as amorphous silicon and polycrystalline silicon. However, the present embodiment is not limited thereto, and the active layer 310 may contain various materials. As an alternative embodiment, the active layer 310 may contain an organic semiconductor material or the like.

As another alternative embodiment, the active layer 310 may contain an oxide semiconductor material. For example, the active layer 310 may contain an oxide of a metal element selected from Groups 12, 13, and 14 elements such as zinc (Zn), indium (In), gallium (Ga), tin (Sn), cadmium (Cd), and germanium (Ge), and a combination thereof.

A gate dielectric layer 313 is formed on the active layer 310. The gate dielectric layer 313 serves to isolate the active layer 310 and the gate electrode 320. The gate dielectric layer 313 may be formed into a multilayer or a single layer of a film made of an inorganic substance such as silicon oxide and/or silicon nitride.

The gate electrode 320 is provided on the gate dielectric layer 313. The gate electrode 320 may be connected to a gate line (not illustrated) applying an on/off signal to the TFT.

The gate electrode 320 may be made of a low-resistivity metal. In consideration of adhesion with an adjacent layer, surface flatness of layers to be stacked, and processability, the gate electrode 320 may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer dielectric film 315 is provided on the gate electrode 320. The interlayer dielectric film 315 isolates the source electrode 330a and the drain electrode 330b, and the gate electrode 320. The interlayer dielectric film 315 may be formed into a multilayer or single layer of a film made of an inorganic substance. For example, the inorganic substance may be a metal oxide or a metal nitride. Specifically, the inorganic substance may include silicon dioxide (SiO₂), silicon nitrides (SiNₓ), silicon oxynitride (SiON), aluminum oxide (Al₂O₃), titanium dioxide (TiO₂), tantalum pentoxide (Ta₂O₅), hafnium dioxide (HfO₂), or zirconium dioxide (ZrO₂).

The source electrode 330a and the drain electrode 330b are provided on the interlayer dielectric film 315. The source electrode 330a and the drain electrode 330b may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is provided on the TFT. The planarization layer 317 is configured to cover the TFT, thereby eliminating steps caused by the TFT and planarizing the top surface. The planarization layer 317 may be formed into a single layer or a multilayer of a film made of an organic substance. The organic substance may include a general-purpose polymer such as polymethyl methacrylate (PMMA) and polystyrene (PS); a polymer derivative having phenols; polyacrylates; polyimides, poly(aryl ethers); polyamides; fluoropolymers; poly-p-xylenes; and polyvinyl alcohols; and a combination thereof. In addition, the planarization layer 317 may be formed into a multi-stack including an inorganic insulating layer and an organic insulating layer.

A first electrode 510 is provided on the planarization layer 317. The first electrode 510 may be electrically connected to the TFT. Specifically, the first electrode 510 may be electrically connected to the drain electrode 330b through a contact hole formed in the planarization layer 317. The first electrode 510 may have various shapes. For example, the first electrode 510 may be patterned in an island layout. A bank layer 400 defining a pixel region may be disposed on the planarization layer 317. The bank layer 400 may include a recess where the micro LED 100 will be received. The bank layer 400 may include, for example, a first bank layer 410 defining the recess. A height of the first bank layer 410 may be determined by a height and viewing angle of the micro LED 100. A size (width) of the recess may be determined by resolution, pixel density, and the like, of a display device. In an embodiment, the height of the micro LED 100 may be greater than the height of the first bank layer 410. The recess may have a quadrangular cross section, but is not limited to this. The recess may have various cross section shapes, such as polygonal, rectangular, circular, conical, elliptical, and triangular.

The bank layer 400 may further include a second bank layer 420 on the first bank layer 410. The first bank layer 410 and the second bank layer 420 have a step difference, and a width of the second bank layer 420 may be smaller than the width of the first bank layer 410. A conductive layer 550 may be disposed on the second bank layer 420. The conductive layer 550 may be disposed in a direction parallel to a data line or a scan line, and may be electrically connected to a second electrode 530. However, the present invention is not limited thereto. The second bank layer 420 may be omitted, and the conductive layer 550 may be disposed on the first bank layer 410. Alternatively, the second bank layer 420 and the conductive layer 550 may be omitted, and the second electrode 530 may be formed over the entire second substrate 301 such that the second electrode 530 serves as a shared electrode that pixels (P) share. The first bank layer 410 and the second bank layer 420 may include a material absorbing at least a part of light, a light reflective material, or a light scattering material. The first bank layer 410 and the second bank layer 420 may include an insulating material that is translucent or opaque to visible light (e.g., light in a wavelength range of 380 nm to 750 nm).

For example, the first bank layer 410 and the second bank layer 420 may be formed of a thermoplastic such as polycarbonate (PC), polyethylene terephthalate (PET), polyethersulfone, polyvinyl butyral, polyphenylene ether, polyamide, polyetherimide, polynorbornene, poly(methyl methacrylate) resin, and cyclic polyolefin resin, a thermosetting plastic such as epoxy resin, phenolic resin, urethane resin, acrylic resin, vinyl ester resin, polyimide resin, urea resin, and melamine resin, or an organic insulating substance such as polystyrene, polyacrylonitrile, and polycarbonate, but are not limited thereto.

As another example, the first bank layer 410 and the second bank layer 420 may be formed of an inorganic insulating substance such as inorganic oxide and inorganic nitride including SiOₓ, SiNₓ, SiNₓO_{y}, AlOₓ, TiOₓ, TaOₓ, and ZnOₓ, but are not limited thereto. In an embodiment, the first bank layer 410 and the second bank layer 420 may be formed of an opaque material such as a material of a black matrix. A material of the insulating black matrix may include a resin or a paste including organic resin, glass paste, and black pigment; metal particles such as nickel, aluminum, molybdenum, and alloys thereof; metal oxide particles (e.g., chromium oxide); metal nitride particles (e.g., chromium nitride), or the like. In an alternate embodiment, the first bank layer 410 and the second bank layer 420 may be a distributed Bragg reflector (DBR) having high reflectivity or a mirror reflector formed of metal.

The micro LED 100 is disposed in the recess. The micro LED 100 may be electrically connected to the first electrode 510 at the recess.

The micro LED 100 emits light having wavelengths of different colors such as red, green, blue, white, and the like. With the micro LED 100, it is possible to realize white light by using fluorescent materials or by combining colors. The micro LED 100 has a size of 1 μm to 100 μm. The micro LEDs 100 are picked up from the first substrate 101 individually or collectively by a transfer head according to the embodiment of the present invention, transferred to the second substrate 301, and received in the recess of the second substrate 301.

The micro LED 100 includes a p-n diode, the first contact electrode 106 disposed on one side of the p-n diode, and the second contact electrode 107 disposed on the opposite side of the first contact electrode 106. The first contact electrode 106 may be connected to the first electrode 510, and the second contact electrode 107 may be connected to the second electrode 530.

The first electrode 510 may include: a reflective layer formed of Ag, Mg, Al, Pt, Pd, Au, Ni, Nd, Ir, Cr, or a compound thereof; and a transparent or translucent electrode layer provided on the reflective layer. The transparent or translucent electrode layer may be formed of at least one selected from among the group consisting of indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds the micro LED 100 in the recess. The passivation layer 520 covers the recess and the first electrode 510 by filling a space between the bank layer 400 and the micro LED 100. The passivation layer 520 may be formed of an organic insulating substance. For example, the passivation layer 520 may be formed of acrylic, poly (methyl methacrylate) (PMMA), benzocyclobutene (BCB), polyimide, acrylate, epoxy, and polyester, but is not limited thereto.

The passivation layer 520 is formed to have a height not covering an upper portion of the micro LED 100, for example, a height not covering the second contact electrode 107, whereby the second contact electrode 107 is exposed. The second electrode 530 may be formed on the passivation layer 520 electrically connected to the exposed second contact electrode 107 of the micro LED 100.

The second electrode 530 may be disposed on the micro LED 100 and the passivation layer 520. The second electrode 530 may be formed of a transparent conductive material such as ITO, IZO, ZnO, and In₂O₃.

Hereinbelow, the transfer head 1000 will be described.

As illustrated in FIG. 1, the transfer head 1000 is disposed between the first substrate 101 and the second substrate 301 in the transfer chamber 11, which means that the transfer head 1000 is provided to be movable between the first base 21 and the second base 22 along the X-axis, and functions to transfer the micro LEDs 100 from the first substrate 101 to the second substrate 301.

In addition, the transfer head 1000 is movable in the Y-axis in the transfer chamber 11, that is, movable up and down.

Since the transfer head 1000 is movable along the X-axis and the Y-axis as described above, the transfer head 1000 grips and transfers the micro LEDs 100 of the first substrate 101 seated on the first base 21 to the second substrate 301 seated on the second base 22. Accordingly, it is possible to easily transfer the micro LEDs 100 from the first substrate 101 to the second substrate 301.

As illustrated in FIG. 4, the transfer head 1000 includes a porous member 1100 having pores. The transfer head 1000 functions to apply a suction force to pores of the porous member 1100 or to release the suction force applied to the pores in order to transfer the micro LEDs 100 from the first substrate 101 to the second substrate 301.

The porous member 1100 is provided with a suction chamber 1200 at an upper portion thereof. The suction chamber 1200 is connected to a suction port supplying a suction force or releasing a suction force. The suction chamber 1200 functions to apply a suction force to the multiple pores of the porous member 1100 or to release a suction force applied to the pores according to the operation of the suction port. A structure of engaging the suction chamber 1200 to the porous member 1100 is not limited as long as the structure is suitable for preventing gas or air from leaking to other parts when applying the suction force to the porous member 1100 or releasing the applied suction force.

The gripping of the micro LEDs 100 by the above-described suction chamber 1200 may be realized by vacuum-suction. Therefore, in the following description, the description will be based on the transfer head 1000 gripping the micro LEDs 100 by vacuum-suction.

When gripping the micro LEDs 100 with vacuum-suction, the vacuum applied to the suction chamber 1200 is transferred to the multiple pores of the porous member 1100 to generate a vacuum suction force for the micro LEDs 100. When detaching the micro LEDs 100, the vacuum applied to the suction chamber 1200 is released to remove the vacuum from the multiple pores of the porous member 1100 whereby the vacuum suction force to the micro LEDs 100 is removed.

The porous member 1100 may be composed of a material containing a large number of pores therein, and may be configured as powders, a thin film, a thick film, or a bulk form having a porosity of about 0.2 to 0.95 in a predetermined arrangement or disordered pore structure. The pores of the porous member 1100 are classified according to pore sizes thereof: micropores having a pore diameter of 2 nm or less, mesopores having a pore diameter of 2 nm to 50 nm, and macropores having a pore diameter of 50 nm or more. The porous member 1100 may include includes at least some of micropores, mesopores, and macropores. Porous materials of the porous member 1100 are classified according to constituent components thereof: organic, inorganic (ceramic), metal, and hybrid type. The porous member 1100 includes an anodic oxide film in which pores are formed in a predetermined arrangement. The porous member 1100 is configured as powders, a coating film, or bulk. The powder may have various shapes such as a sphere, a hollow sphere, a fiber, and a tube. The powder may be used as it is in some cases, but it is also possible to prepare a coating film or a bulk shape with the powder as a starting material.

When the pores of the porous member 1100 have a disordered pore structure, the multiple pores are connected to each other inside the porous member 1100 such that air flow paths are formed which connects upper and lower portions of the porous member 1100. When the pores of the porous member 1100 have a vertical pore structure, the inside of the porous member 1100 is pierced from top to bottom by the vertical pores such that air flow paths are formed.

The porous member 1100 includes a suction region 1110 gripping the micro LEDs 100 and a non-suction region 1130 not gripping the micro LEDs 100. The suction region 1110 is a region where vacuum of the suction chamber 1200 is transferred and grips the micro LEDs 100. The non-suction region 1130 is a region where the vacuum of the suction chamber 1200 is not transferred and thus does not grip the micro LEDs 100.

The non-suction region 1130 may be embodied by forming a shielding portion on at least a part of a surface of the porous member 1100. The shielding portion is formed to close the pores exposed at least a part of a surface of the porous member 1100. The shielding portion may be formed on at least a part of upper and lower surfaces of the porous member 1100. In particular, in the case where the porous member 1100 has a disordered pore structure, the shielding portion may be formed on both the upper and lower surfaces of the porous member 1100.

The shielding portion is not limited in material, shape, and thickness as long as the shielding portion functions to close the pores exposed to the surface of the porous member 1100. Preferably, the shielding portion may be further provided and formed of a photoresist (PR, including dry film PR) or a metal or may be provided by the own structure of the porous member 1100. In the case the shielding portion is provided by the structure of the porous member 1100, for example, in the case the porous member 1100 to be described later is formed of an anodic oxide film, the shielding portion may be a barrier layer or a metal base material.

A size of a horizontal area of each suction region 1110 may be smaller than a size of a horizontal area of an upper surface of each micro LED 100 to prevent vacuum leakage while the micro LED 100 is gripped by vacuum-suction, whereby it is possible to perform vacuum-suction easily.

The transfer head 1000 may be provided with a monitoring unit monitoring the degree of vacuum of the suction chamber 1200. The monitoring unit may monitor the degree of vacuum generated in the suction chamber 1200, and a control unit may control the degree of vacuum of the suction chamber 1200 according to the degree of vacuum of the suction chamber 1200. When the monitoring unit monitors that the degree of vacuum of the suction chamber 1200 is lower than a predetermined range of the degree of vacuum, the control unit may determine that some of the micro LEDs 100 to be vacuum-sucked on the porous member 1100 are not vacuum-sucked or may determine that there is leakage of the vacuum, and thus instruct the transfer head 1000 to operate again. As described above, the transfer head 1000 transfers the micro LEDs 100 without error according to the degree of vacuum in the suction chamber 1200.

In addition, the transfer head 1000 may be provided with a buffer member to buffer contact between the porous member 1100 and the micro LEDs 100. A material of the buffer member is not limited as long as the buffer member can buffer the contact between the porous member 1100 and the micro LED 100 and has an elastic force. The buffer member may be provided between the porous member 1100 and the suction chamber 1200, but a position where the buffer member is mounted is not limited thereto. The buffer member may be provided at any position of the transfer head 1000 as long as the buffer member at a certain position can buffer the contact between the porous member 1100 and the micro LED 100.

In the case where a pitch distance of the micro LEDs 100 on the first substrate 101 is P(n) in a column direction and a pitch distance of the micro LEDs 100 on the growth substrate 101 in a row direction is P(m), the suction region 1110 may be provided with pitch distances equal to the pitch distances of the micro LEDs 100 on the first substrate 101 as illustrated in FIG. 5A. In other words, when the pitch distances of the micro LEDs 100 on the first substrate 101 are P(n) in the column direction and P(m) in the row direction, pitch distances of the suction region 1110 of the transfer head 1000 are P(n) in a column direction and P(m) in a row direction. According to the above configuration, the transfer head 1000 vacuum-sucks all of the micro LEDs 100 on the first substrate 101 at the same time.

Alternatively, when pitch distances of the micro LEDs 100 on the first substrate 101 are P(n) in the column direction and P(m) in the row direction, pitch distances of the suction region 1110 of the transfer head 1000 are 3p(n) in a column direction and p(m) in a row direction as illustrated in FIG. 5B. Here, 3p(n) means 3 times the column pitch distance p(n) illustrated in FIG. 5A.

According to the above configuration, only the micro LEDs 100 at (3n)th column is vacuum-sucked and transferred. Here, each of the micro LEDs 100 transferred in the (3n)th column may be any one of red, green, blue, and white LEDs. With such a configuration, it is possible to transfer the micro LEDs 100 of the same luminous color mounted on the second substrate 301 at distances of 3p(n).

Alternatively, when pitch distances of the micro LEDs 100 on the first substrate 101 are P(n) in the column direction and P(m) in the row direction, pitch distances of the suction region 1110 of the transfer head 1000 are p(n) in a column direction and 3p(m) in a row direction as illustrated in FIG. 5C. Here, 3p (m) means 3 times the row pitch distance p(m) illustrated in FIG. 5A. According to the above configuration, only the micro LEDs 100 at (3n)th row is vacuum-sucked and transferred. Here, each of the micro LEDs 100 transferred in the (3n)th row may be any one of red, green, blue, and white LEDs. With such a configuration, it is possible to transfer the micro LEDs 100 of the same luminous color mounted on the second substrate 301 at distances of 3p(m).

Alternatively, when pitch distances of the micro LEDs 100 on the first substrate 101 are P(n) in the column direction and P(m) in the row direction, the suction region 1110 is configured in a diagonal direction such that pitch distances of the suction region 1110 of the transfer head 1000 are 3p(n) in a column direction and 3p(m) in a row direction as illustrated in FIG. 5D. Here, each of the micro LEDs 100 transferred in the (3n)th row and (3n)th column may be any one of red, green, blue, and white LEDs. According to the above configuration, by arranging the micro LEDs 100 of the same luminous color to be mounted on the second substrate 301 with distances of 3p(n) and 3p(m), the micro LEDs 100 of the same luminous color are transferred in the diagonal direction.

In the case of the present invention, since the micro LED 100 has a circular cross-section, the suction region 1110 is also formed in a circular shape as illustrated in FIGS. 5A to 5D. However, the shape of the suction region 1110 may vary depending on the cross-sectional shape of the micro LED 100. For example, when the micro LED 100 has a quadrangular cross-section, the suction region 1110 may have a quadrangular cross-section corresponding to the cross-sectional shape of the micro LED 100.

Hereinbelow, a process for a transfer method using the transfer head 1000 will be described with reference to FIGS. 6A to 6D.

Referring to FIG. 6A, the micro LEDs 100 formed on the first substrate 101 are prepared to be separable from the first substrate 101.

Next, referring to FIG. 6B, the transfer head 1000 is moved above the first substrate 101 and then lowered.

At this point, the porous member 1100 is applied with vacuum pressure through the suction port to vacuum-suck the micro LEDs 100. When the transfer head 1000 grips the micro LEDs 100 by a suction force, the porous member 1100 of the transfer head 100 may be brought in close contact with the micro LEDs 100 while gripping the micro LEDs 100 by vacuum-suction. However, the micro LEDs 100 may be damaged by the close contact with the porous member 1100. Thus, the micro LEDs 100 may be gripped on a lower surface of the porous member 1100 by a vacuum suction force while the lower surface of the porous member 1100 and upper surfaces of the micro LEDs 100 are spaced apart from each other by a predetermined distance.

Then, as illustrated in FIG. 6C, the transfer head 1000 is lifted and moved while the vacuum suction force of the transfer head 1000 to the micro LEDs 100 is maintained.

Thereafter, as illustrated in FIG. 6D, the transfer head 1000 is moved above the second substrate 301 and then lowered. At this point, the micro LEDs 100 are transferred to the second substrate 301 by releasing the vacuum applied to the porous member 1100 through the suction port.

According to the above process sequence, the transfer head 1000 can transfer the micro LEDs 100 formed on the first substrate 101 to the second substrate 301 and mount the micro LEDs 100.

Hereinbelow, the spraying unit will be described.

The spraying unit is provided in the transfer chamber 11 and functions to spray the ionized gas G.

The spraying unit may include: a supply portion supplying gas; a nozzle spraying the gas; a pair of electrodes connected to a power source; a controller controlling the power source; and a booster connected to the electrodes.

Therefore, when positive and negative DC voltages are raised to a predetermined voltage in accordance with a signal from the controller and the voltages are alternately applied to the pair of electrodes at regular intervals, a corona discharge is generated at the ends of the pair of electrodes.

As described above, when the corona discharge occurs and the supply portion supplies gas to the pair of electrodes, the supplied gas is ionized, and the nozzle sprays the ionized gas G.

The ionized gas G spayed by the spraying unit functions to prevent the generation of an electrostatic force in at least one of the micro LEDs 100 formed on the first substrate 101, the micro LEDs 100 mounted on the second substrate 301, and the transfer head 1000.

In detail, an electrostatic force caused by electrification may undesirably occur between the first substrate 101 and the transfer head 1000 or between the second substrate 301 and the transfer head 1000 due to friction or the like during the transfer process of the transfer head 1000.

This undesirable electrostatic force has a great influence on the micro LEDs 100 having a size of 1 μm to 100 μm even if the electrostatic force is caused by small charge.

In other words, after the transfer head 1000 sucks the micro LEDs 100 from the first substrate 101, if an electrostatic force is generated in the unloading process in which the micro LED 100s are mounted on the second substrate 301, the micro LED 100s may stick to the transfer head 1000 and be unloaded to the second substrate 301 with a wrong position or unloading may not be performed at all.

In this situation, the ionized gas G sprayed by the spraying unit flows in the transfer chamber 11 in a form of gas G in which positive and negative ions are ionized.

The positive and negative ions are moved to a charged part in the first substrate 101, the second substrate 301, and the transfer head 1000 to convert the charged state to a neutral state. For example, when the first substrate 101 is electrified in which positive charges are accumulated on a region thereof, the negative charges of the ionized gas G moves to the region whereby the region is converted to the neutral state.

Therefore, even if at least one of the first substrate 101, the second substrate 301, and the transfer head 1000 is electrified by the ionized gas G sprayed by the spraying unit, it is possible to convert the electrified state to the neutral state and prevent the generation of an electrostatic force thereby.

In the case of the transfer head 1000 in which the micro LEDs 100 are not gripped by the electrostatic force (in the case of the present invention, the micro LEDs 100 are gripped by a suction force), the transfer of the micro LEDs 100 can be easily performed because the spraying unit prevents the generation of an electrostatic force.

In other words, if the electrostatic force is not generated because of the spraying unit, it is possible to prevent the above-mentioned positional error during the unloading of the micro LEDs 100 or the situation that the micro LEDs 100 stick to the transfer head 1000 and thus the unloading of the micro LEDs 100 is not performed at all.

As illustrated in FIG. 1, the above-described spraying unit may be embodied as a spraying unit 51 for the transfer chamber provided at an upper portion of the transfer chamber 11.

The ionized gas G sprayed through the nozzle flows from the upper portion to the lower portion inside the transfer chamber 11 such that the spraying unit 51 forms a downward flow.

The ionized gas G in the downward flow is filled into the transfer chamber 11 such that the atmosphere inside the transfer chamber 11 is replaced with the ionized gas G.

As the ionized gas G is filled into the transfer chamber 11 by the spraying unit 51, the positive and negative ions flow in the transfer chamber 11 in the form of the ionized gas G.

As described above, since the spraying unit 51 replaces the atmosphere in the transfer chamber 11 with the ionized gas G, it is possible to prevent the generation of the electrostatic force on the first substrate 101, the second substrate 301, and the transfer head 1000, thereby preventing the occurrence of errors and damage to the micro LEDs 100 during the transfer process.

Unlike the above, the spraying unit 51 may be provided at any position other than the upper portion of the transfer chamber 11, for example, on a side or the lower portion of the transfer chamber 11, etc., as long as the atmosphere in the transfer chamber 11 is replaced with the ionized gas G by the spraying unit 51.

The first passage 14 and the second passage 16 may be provided with a spraying unit 55 for the first passage and a spraying unit 56 for the second passage, which have the same functions as the spraying unit described above.

When the first base 21 is moved along the X-axis from the loading chamber 13 to the transfer chamber 11 through the first passage 14, the spraying unit 55 functions to spray the ionized gas onto an upper surface of the first substrate 101 seated on the first base 21. Therefore, it is possible to prevent the generation of an electrostatic force on the first substrate 101 during transfer of the first substrate 101 through the first passage 14.

When the second base 22 is moved along the X-axis from the transfer chamber 11 to the unloading chamber 15 through the second passage 16, the spraying unit 56 functions to spray the ionized gas onto an upper surface of the second substrate 301 seated on the second base 22. Therefore, it is possible to prevent the generation of an electrostatic force on the second substrate 301 during transfer of the second substrate 301 through the second passage 16.

System 10′ for Transferring a Micro LED According to a Second Embodiment of the Present Invention

Hereinbelow, a system 10′ for transferring a micro LED according to a second embodiment of the present invention will be described.

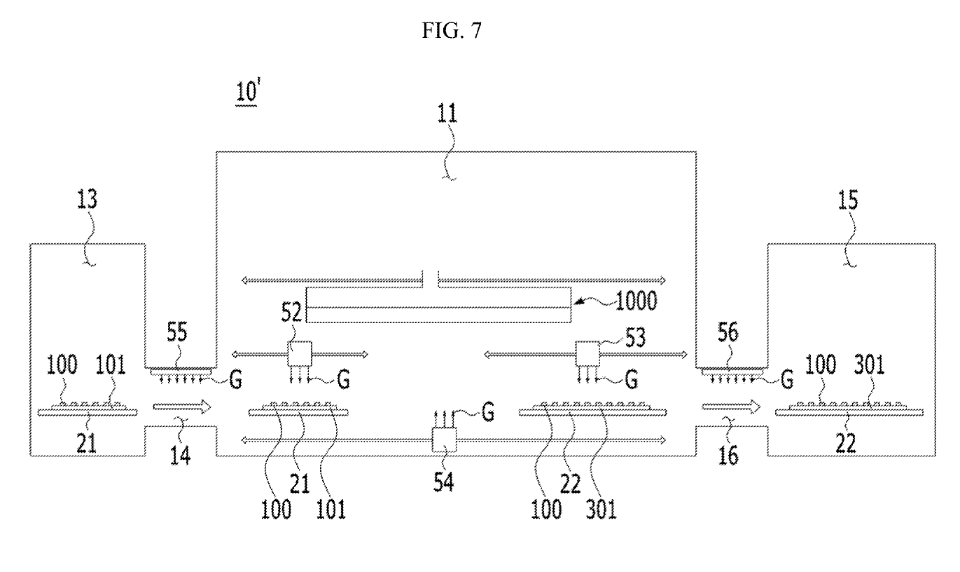

FIG. 7 is a view illustrating a system for transferring a micro LED according to a second embodiment of the present invention.

The system 10′ for transferring a micro LED according to the second embodiment of the present invention differs from the system 10′ for transferring a micro LED according to the first embodiment of the present invention in the configuration of the spraying unit, but other configurations are the same. Therefore, a description of the components of the system 10′ for transferring a micro LED according to the second embodiment of the present invention can be substituted by the above description.

As illustrated in FIG. 7, a spraying unit of the system 10′ for transferring a micro LED according to the second embodiment of the present invention includes: a spraying unit 52 for the first substrate spraying the ionized gas G on the upper surface of the first substrate 101; a spraying unit 53 for the second substrate 102 spraying the ionized gas G on the upper surface of the second substrate 301; and a spraying unit 54 for the transfer head spraying the ionized gas G on lower surfaces of the micro LEDs 100 gripped by the transfer head 1000.

The spraying unit 52 is provided in the transfer chamber 11 to be positioned above the first substrate 101 and functions to spray the ionized gas G on the upper surface of the first substrate 101. In this case, the spraying unit 52 ionizes the supplied gas and sprays the ionized gas G through a nozzle by the same operating principle as that of the above-described spraying unit.

The spraying unit 52 is disposed above the first substrate 101 disposed in the transfer chamber 11, that is, above the first base 21 moved to the transfer chamber 11, and provided to be movable in the X-axis and the Y-axis.

As described above, since the spraying unit 52 is provided to be movable in the X-axis and the Y-axis, it is possible to prevent the spraying unit 52 from interfering with the movement of the transfer head 1000.

The spraying unit 53 is provided in the transfer chamber 11 to be positioned above the second substrate 301 and functions to spray the ionized gas G on the upper surface of the second substrate 301. In this case, the spraying unit 53 ionizes the supplied gas and sprays the ionized gas G through a nozzle by the same operating principle as that of the above-described spraying unit.

The spraying unit 53 is disposed above the second substrate 301 disposed in the transfer chamber 11, that is, above the second base 22 moved to the transfer chamber 11, and provided to be movable in the X-axis and the Y-axis.

As described above, since the spraying unit 53 is provided to be movable in the X-axis and the Y-axis, it is possible to prevent the spraying unit 53 from interfering with the movement of the transfer head 1000.

The spraying unit 54 is provided in the transfer chamber 11 to be positioned below the transfer head 1000 and functions to spray the ionized gas G on the lower surface of the transfer head 1000 or the lower surfaces of the micro LEDs 100 gripped by the transfer head 1000. In this case, the spraying unit 54 ionizes the supplied gas and sprays the ionized gas G through a nozzle by the same operating principle as that of the above-described spraying unit.

The spraying unit 54 is disposed below the transfer head 1000 disposed in the transfer chamber 11 and provided to be movable in the X-axis and the Y-axis.

As described above, since the spraying unit 54 is provided to be movable in the X-axis and the Y-axis, it is possible to prevent the spraying unit 54 from interfering with the movement of the transfer head 1000.

Compared with the system 10′ for transferring a micro LED according to the first embodiment of the present invention, the system 10′ for transferring a micro LED according to the second embodiment of the present invention is provided with the spraying unit 52, the spraying unit 53, and the spraying unit 54 whereby it is possible to prevent the generation of the electrostatic force with a small amount of gas.

In other words, the spraying unit 52, the spraying unit 53, and the spraying unit 54 spray the ionized gas G on the upper surface of the first substrate 101 (or on the upper surfaces of the micro LEDs 100 formed on the first substrate 101), on the upper surface of the second substrate 301 (or on the upper surfaces of the micro LEDs 100 mounted on the second substrate 301), and on the lower surface of the transfer head 1000 (or on the lower surfaces of the micro LEDs 100 gripped by the transfer head 1000), respectively. Accordingly, the ionized gas G is sprayed only to the region where the electrification is generated whereby it is possible to not only prevent the generation of the electrostatic force but also reduce the amount of gas used.

In addition, since the spraying unit 52, the spraying unit 53, and the spraying unit 54 inject the ionized gas G intensively on the respective regions, it is possible to prevent the positive or negative ions from not reaching the charged regions (i.e., it is possible to minimize a region where the positive or negative ions can not reach). As a result, it is possible to effectively convert the charged region into a neutral state.

The transfer head 1000 provided in the system 10 for transferring a micro LED according to the first embodiment of the present invention and in the system 10′ for transferring a micro LED according to the second embodiment of the present invention may have various modifications.

Hereinbelow, first to thirteenth modifications of the transfer head 1000 will be described, wherein the transfer head 1000 being provided in the system 10 for transferring a micro LED according to the first embodiment of the present invention and in the system 10′ for transferring a micro LED according to the second embodiment of the present invention.

First Modification of the Transfer Head 1000

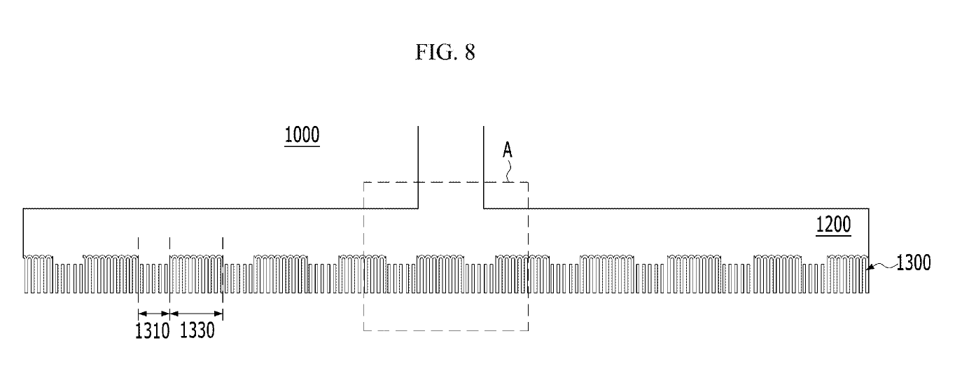

Hereinbelow, a first modification of the transfer head 1000 will be described with reference to FIGS. 8 to 10.

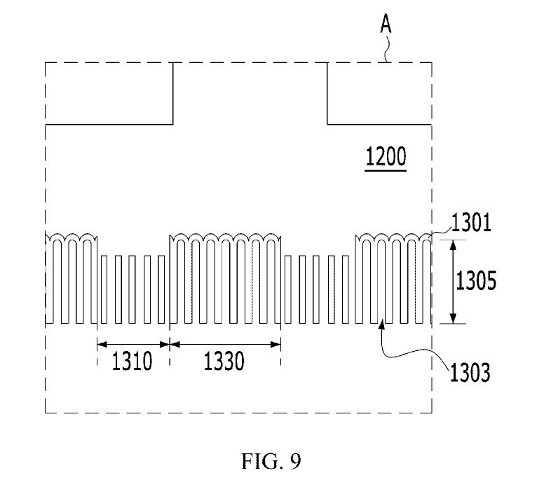

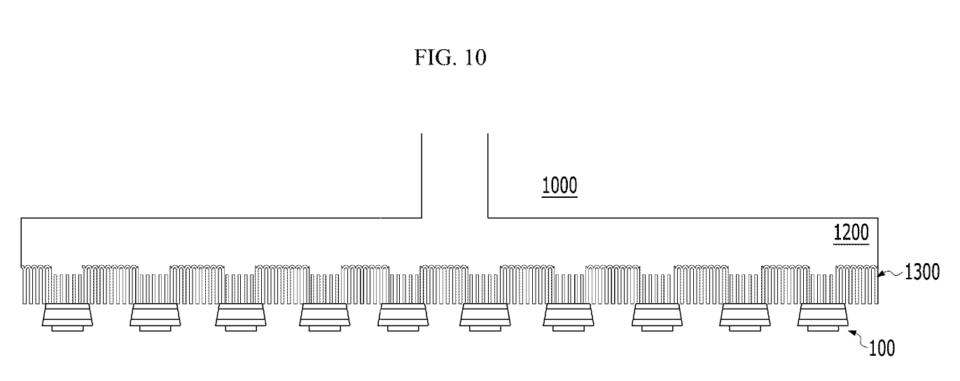

FIG. 8 is a view illustrating a first modification of the transfer head according to the present invention; FIG. 9 is an enlarged view of a portion ‘A’ of FIG. 8; and FIG. 10 is a view illustrating a state in which the transfer head of FIG. 8 grips the micro LEDs.

As illustrated in FIGS. 8 to 10, the first modification of the transfer head 1000 is provided with the anodic oxide film 1300, which is provided in the transfer head 1000 of the system 10 for transferring a micro LED according to the first embodiment of the present invention and configured such that the porous member 1100 is embodied by the anodic oxide film 1300 having pores formed by anodizing a metal.

The anodic oxide film 1300 is a film formed by anodizing a metal that is a base material, and the pores 1303 are pores formed in a process of forming the anodic oxide film 1300 by anodizing the metal.

For example, in a case that the base metal is aluminum (Al) or an aluminum alloy, the anodization of the base material forms the anodic oxide film 1300 consisting of anodized aluminum (Al₂O₃) on a surface of the base material. The anodic oxide film 1300 formed as described above includes a barrier layer 1301 in which pores 1303 are not formed and a porous layer in which the pores 1303 are formed inside.

The barrier layer 1301 is positioned on top of the base material and the porous layer is positioned on top of the barrier layer 1301.

After removing the base material on which the anodic oxide film 1300 having the barrier layer 1301 and the porous layer is formed, only anodic oxide film 1300 consisting of anodized aluminum (Al₂O₃) remains.

The anodic oxide film 1300 has the pores 1303 configured vertically and having a regular arrangement with a uniform diameter. Accordingly, after removing the barrier layer 1301, the pores 1303 have a structure extending from top to bottom vertically, thereby facilitating the generation of the vacuum pressure in the vertical direction.

The inside of the anodic oxide film 1300 forms an air flow path vertically by the vertical pores 1303.

An internal width of the pores 1303 has a size of several nanometers to several hundred nanometers. For example, when a size of the micro LED to be vacuum-sucked is 30 μm×30 μm and an internal width of the pores 1303 is several nanometers, it is possible to vacuum-suck the micro LEDs 100 by approximately tens of millions of pores 1303.

When a size of the micro LED to be vacuum-sucked is 30 μm×30 μm and an internal width of the pores 1303 is several hundred nanometers, it is possible to vacuum-suck the micro LEDs 100 by approximately tens of thousands of pores 1303.

The micro LED 100 is lightweight because the micro LED 100 is fundamentally configured with the first semiconductor layer 102, the second semiconductor layer 104, the active layer 103 provided between the first semiconductor layer 102 and the second semiconductor layer 104, the first contact electrode 106, and the second contact electrode 107. Accordingly, it is possible to grip the micro LEDs 100 by tens of thousands to tens of millions of pores 1303 formed in the anodic oxide film 1300 by vacuum-suction.

The suction chamber 1200 is provided on the anodic oxide film 1300.

The suction chamber 1200 is connected to a suction port providing vacuum pressure. The suction chamber 1200 functions to vacuum the multiple vertical pores of the anodic oxide film 1300 or release the vacuum according to the operation of the suction port.

When gripping the micro LEDs 100, the vacuum applied to the suction chamber 1200 is transferred to the multiple pores 1303 of the anodic oxide film 1300 to provide a vacuum suction force for the micro LEDs 100. When detaching the micro LEDs 100, the vacuum applied to the suction chamber 1200 is released to remove the vacuum from the multiple pores 1303 of the anodic oxide film 1300 whereby the vacuum suction force to the micro LEDs 100 is removed.

The anodic oxide film 1300 includes a suction region 1310 gripping the micro LEDs 100 by vacuum-suction and a non-suction region 1330 not gripping the micro LEDs 100.

The suction region 1310 is a region where vacuum of the suction chamber 1200 is transferred and grips the micro LEDs 100 by vacuum-suction. The non-suction region 1330 is a region where vacuum of the suction chamber 1200 is not transferred and thus does not grip the micro LEDs 100.

Preferably, the suction region 1310 is a region where the pores 1303 extend from top to bottom vertically, and the non-suction region 1330 is a region where at least any one of upper and lower portions of the pores 1303 is closed.

The non-suction region 1330 may be embodied by forming a shielding portion on at least a part of a surface of the anodic oxide film 1300. The shielding portion is formed to close openings of the pores 1303 exposed to at least a part of the surface of the anodic oxide film 1300.

The shielding portion may be formed on at least a part of upper and lower surfaces of the anodic oxide film 1300. The shielding portion is not limited in material, shape, and thickness as long as the shielding portion functions to close the openings of the pores 1303 exposed to the surface of the porous member 1100. Preferably, the shielding portion may be further provided and formed of a photoresist (PR, including dry film PR) or a metal, and the barrier layer 1301 may be the shielding portion.

The non-suction region 1330 may be formed such that the barrier layer 1301 formed in the fabrication of the anodic oxide film 1300 closes any one of the upper and lower portions of the vertical pores 1303. The suction region 1310 may be formed such that the barrier layer 1301 is removed by etching or the like so that the upper and lower portions of the vertical pores 1303 extend from top to bottom.

In addition, a thickness of the anodic oxide film 1300 in the suction region 1310 is smaller than a thickness of the anodic oxide film 1300 in the non-suction region 1330 because the pores 1303 extending from top to bottom are formed by removing a part of the barrier layer 1301.

FIG. 8 illustrates that the barrier layer 1301 is provided at an upper portion of the anodic oxide film 1300 and the porous layer 1305 having the pores 1303 is provided at a lower portion thereof. However, the anodic oxide film 1300 illustrated in FIG. 8 may be inverted to form the non-suction region 1330 such that the barrier layer 1301 is provided at the lower portion of the anodic oxide film 1300.

It has been described the non-suction region 1330 that any one of the upper and lower portions of the pores 1303 is closed by the barrier layer 1301. However, the opposite surface, which is not closed by the barrier layer 1301, may be configured such that an additional coating layer is provided to close both the upper and lower portions. In forming the non-suction region 1330, the configuration in which both the upper and lower surfaces of the anodic oxide film 1300 are closed is advantageous in that it is possible to reduce the possibility that foreign substances remain in the pores 1303 of the non-suction region 1330 compared with the configuration in which at least one of the upper and lower surfaces of the anodic oxide film 1300 is closed.

Second Modification of the Transfer Head 1000

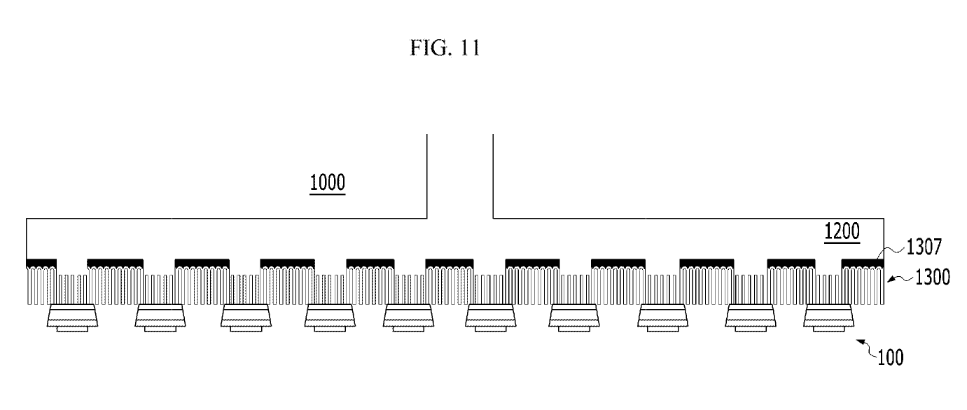

Hereinbelow, a second modification of the transfer head 1000 will be described with reference to FIG. 11.

FIG. 11 is a view illustrating a state in which a second modification of the transfer head grips the micro LEDs.

As illustrated in FIG. 11, the second modification of the transfer head 1000 is configured such that a supporting portion 1307 is further provided on the non-suction region 1330 to reinforce the strength of the anodic oxide film 1300.

For example, the supporting portion 1307 may be formed of a metal base material.

The metal base material used for the anodization is not removed and left on the barrier layer 1301 such that the metal base material may serve as the supporting portion 1307.

Referring to FIG. 11, the non-suction region 1330 is configured with the supporting portion 1307 formed of the metal, the barrier layer 1301, and the porous layer 1305 having the pores 1303. As the supporting portion 1307 formed of the metal and the barrier layer 1301 are removed, the suction region 1310 is formed in a manner that the upper and lower portions of the pores 1303 extend from top to bottom.

The supporting portion 1307 formed of the metal is provided in the non-suction region 1330 to secure the strength of the anodic oxide film 1300.

As the strength of the anodic oxide film 1300 which has a relatively weak strength is increased due to the above-described configuration of the supporting portion 1307, it is possible to configure the transfer head 1000 having the anodic oxide film 1300 to have a large area.

Third Modification of the Transfer Head 1000

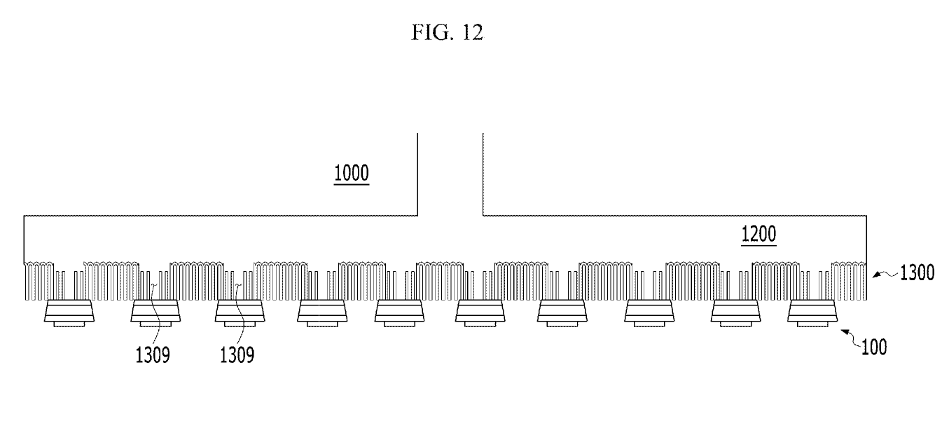

Hereinbelow, a third modification of the transfer head 1000 will be described with reference to FIG. 12.

FIG. 12 is a view illustrating a state in which a third modification of the transfer head grips micro LEDs.

As illustrated in FIG. 12, the third modification of the transfer head 1000 is configured such that a through-hole 1309 is further provided in the suction region 1310 of the anodic oxide film 1300 in addition to the pores 1303 which are formed spontaneously in the anodic oxide film 1300.

The through-hole 1309 is configured to extend from top to bottom of the anodic oxide film 1300 longitudinally.

A diameter of the through-hole 1309 is configured to be larger than those of the pores 1303.

Compared with the configuration in which the micro LEDs 100 are vacuum-sucked by only the pores 1303, it is possible for the third modification to increase the grip surface area for the micro LEDs 100 due to the configuration in which the through-hole 1309 having a diameter larger than those of the pores 1303 is provided.

The through-hole 1309 may be formed by etching the anodic oxide film 1300 vertically after forming the anodic oxide film 1300 and the pores 1303.

By using the etching method for forming the through-hole 1309, it is possible to form the through-hole 1309 stably compared with simply forming the through-hole 1309 by reaming the pores 1303.

In other words, when forming the through-hole 1309 by reaming the pores 1303, side surfaces of the pores 1303 are collapsed, leading to damage to the through-hole 1309, for example, a deformation of the through-hole 1309.

However, by forming the through-hole 1309 by etching, the through-hole 1309 is easily formed without damaging the side surfaces of the pores 1303, thereby preventing damage to the through-hole 1309.

It is preferable that the through-hole 1309 is configured in the center of the suction region 1310 in order to prevent vacuum leakage in the suction region 1310.

With respect to the entire the transfer head 1000, the through-hole 1309 may have different sizes and numbers depending on each position of the suction region 1310.

In the case the suction port is disposed at the center of the transfer head 1000, the vacuum pressure is gradually decreased from the center to the edge of the transfer head 1000, which may cause unevenness of the vacuum pressure among suction regions 1310.

In this case, a suction region formed by the through-hole 1309 in the suction region 1310 disposed at the edge side of the transfer head 1000 may be configured to have a size larger than a suction region formed by the through-hole 1309 in the suction region 1310 disposed at the center side of the transfer head 1000.

By varying the size of the suction region of the through-hole 1309 according to the position of the suction region 1310, it is possible to eliminate unevenness of the vacuum pressure generated among the suction regions 1310 and to provide a uniform vacuum suction force.

Fourth Modification of the Transfer Head 1000

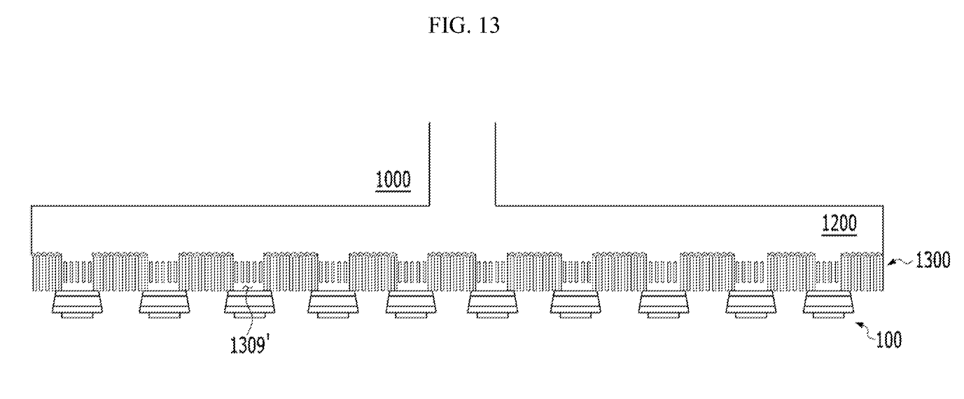

Hereinbelow, a fourth modification of the transfer head 1000 will be described with reference to FIG. 13.

FIG. 13 is a view illustrating a state in which a fourth modification of the transfer head grips the micro LEDs.

As illustrated in FIG. 13, the fourth modification of the transfer head 1000 is configured such that a suction recess 1309′ is further provided in a lower portion of the suction region 1310 of the anodic oxide film 1300.

The suction recess 1309′ have a horizontal area larger than that of the above-described pores 1303 or the through-hole 1309 of FIG. 12, but smaller than that of the upper surface of the micro LED 100.

Accordingly, it is possible to further increase the vacuum suction region for gripping the micro LEDs 100 and to provide a uniform vacuum suction region for gripping the micro LEDs 100 because of the suction recess 1309′.

The suction recess 1309′ may be formed by etching a part of the anodic oxide film 1300 to a predetermined depth after forming the anodic oxide film 1300 and the pores 1303.

Fifth Modification of the Transfer Head 1000

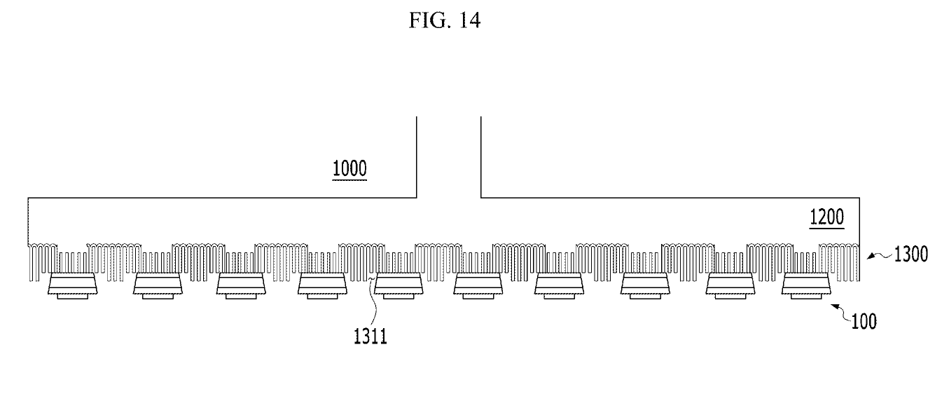

Hereinbelow, a fifth modification of the transfer head 1000 will be described with reference to FIG. 14.

FIG. 14 is a view illustrating a state in which a fifth modification of the transfer head grips the micro LEDs.

As illustrated in FIG. 14, the fifth modification of the transfer head 1000 is configured such that a receiving recess 1311 is further provided in the lower portion of the suction region 1310 of the anodic oxide film 1300.

The receiving recess 1311 has a horizontal area larger than that of the upper surface of the micro LED 100.

As a result, the position of the micro LED 100 is restricted when the transfer head 1000 is moved as the micro LED 100 is inserted into the receiving recess 1311 and is seated.

The receiving recess 1311 may be formed by etching a part of the anodic oxide film 1300 to a predetermined depth after forming the anodic oxide film 1300 and the pores 1303.

Sixth Modification of the Transfer Head 1000

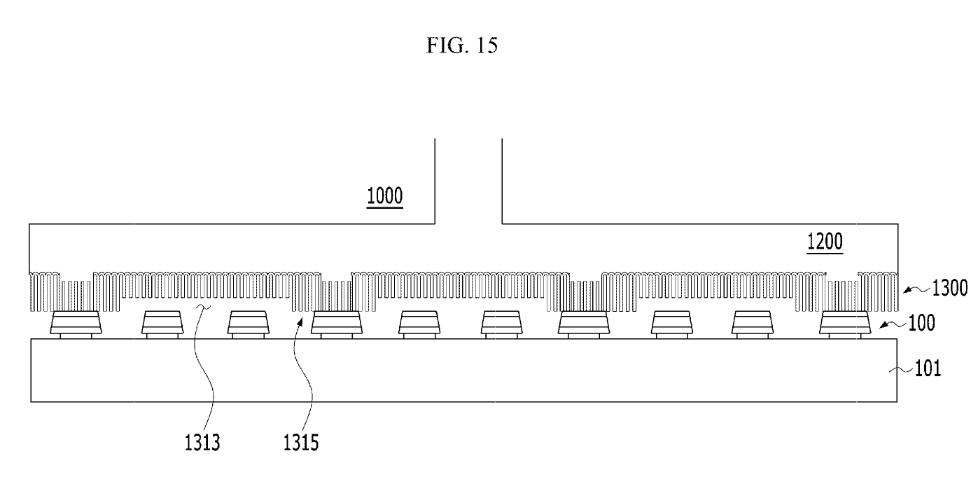

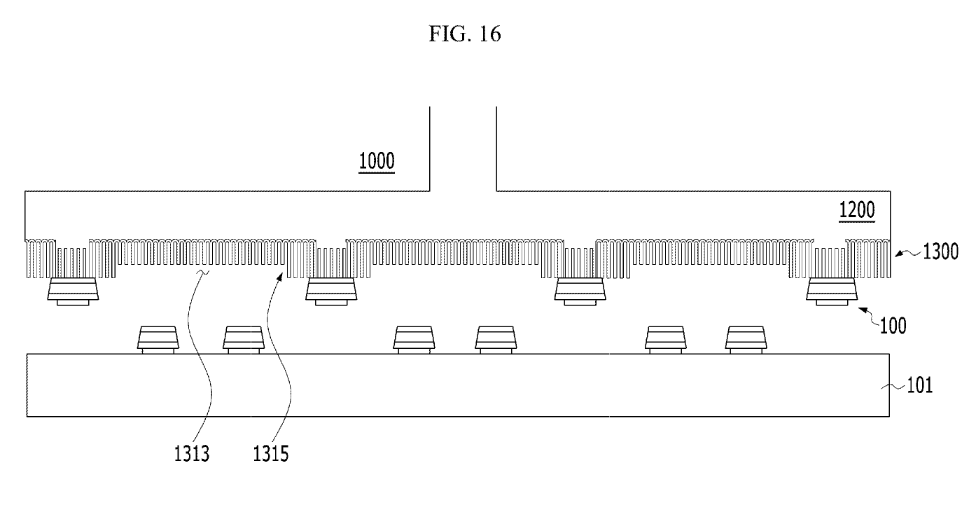

Hereinbelow, a sixth modification of the transfer head 1000 will be described with reference to FIGS. 15 and 16.

FIGS. 15 and 16 are views illustrating a state in which a sixth modification of the transfer head grips the micro LEDs.

As illustrated in FIGS. 15 and 16, the sixth modification of the transfer head 1000 is configured such that an escape recess 1313 is further provided in a lower portion of the non-suction region 1330 of the anodic oxide film 1300.

When the transfer head 1000 descends to vacuum-suck the micro LED 100 at a predetermined position, column, or row, the escape recess 1313 functions to prevent interference of the micro LEDs 100 not to be gripped.

Due to the configuration of the escape recess 1313, a protruding portion 1315 is provided in the lower portion of the suction region 1310.

The protruding portion 1315 protrudes further downward in the vertical direction compared with the escape recess 1313, and the micro LED 100 is gripped at a lower portion of the protruding portion 1315. A horizontal area of the protruding portion 1315 is configured to be equal to or larger than the horizontal area of the suction region 1310.

The horizontal area of the protruding portion 1315 may be configured to be larger than that of the upper surface of the micro LED 100, and a width of the suction region 1310 is configured to be smaller than that of the upper surface of the micro LED 100 in order to prevent the vacuum leakage.

A horizontal area of the escape recess 1313 is configured to be larger than that of at least one micro LED 100.

FIG. 15 illustrates that the escape recess 1313 has a horizontal width equal to a value obtained by summing twice the horizontal width of the two micro LEDs 100 and twice the horizontal pitch distance between the micro LEDs 100. Thus, when descending the transfer head 1000 to vacuum-suck the micro LEDs 100 to be gripped, it is possible to prevent interference of the micro LEDs 100 not to be gripped.

As illustrated in FIGS. 15 and 16, the micro LEDs 100 to be gripped on the first substrate 101 are the micro LEDs 100 at the 1st, 4th, 7th, and 10th positions with reference to the left side of the drawing. The transfer head 1000 having the configuration of the escape recess 1313 vacuum-sucks only the micro LEDs 100 corresponding to the 1st, 4th, 7th, and 10th positions without interference of the micro LEDs 100 not to be gripped.

Seventh Modification of the Transfer Head 1000

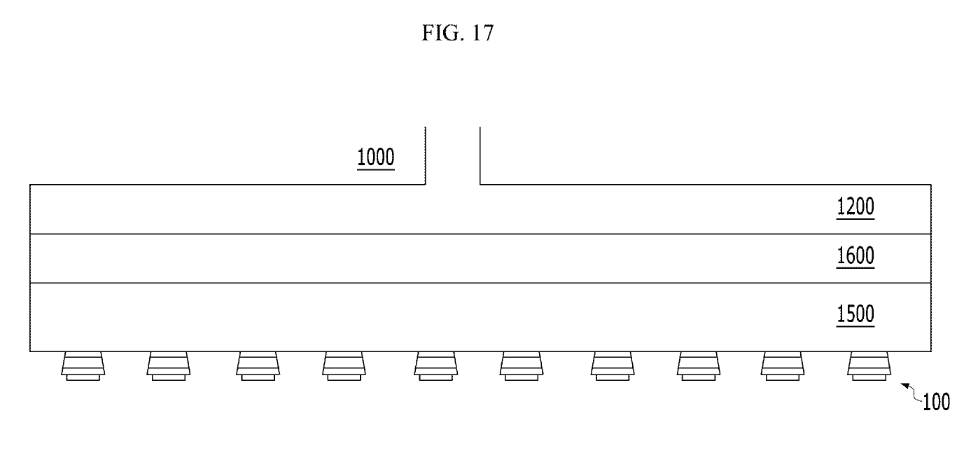

Hereinbelow, a seventh modification of the transfer head 1000 will be described with reference to FIG. 17.

FIG. 17 is a view illustrating a state in which a seventh modification of the transfer head grips the micro LEDs.

As illustrated in FIG. 17, the seventh modification of the transfer head 1000 is configured such that the porous member 1100 of the transfer head 1000 of the system 10 for transferring a micro LED according to the first embodiment is configured to have two porous members including a first porous member 1500 and a second porous member 1600.

The second porous member 1600 is provided on the first porous member 1500. The first porous member 1500 functions to vacuum-suck the micro LEDs 100. The second porous member 1600 is disposed between the suction chamber 1200 and the first porous member 1500 to transfer the vacuum pressure of the suction chamber 1200 to the first porous member 1500.

The first and second porous members 1500 and 1600 may have different porosity characteristics. For example, the first and second porous members 1500 and 1600 have different characteristics in the arrangement and size of the pores, the material and the shape of the porous member.

With respect to the arrangement of the pores, one of the first and second porous members 1500 and 1600 may have a uniform arrangement of pores and the other may have a disordered arrangement of pores.

With respect to the size of the pores, any one of the first and second porous members 1500 and 1600 may have a larger pore size than the other. Here, the size of the pores may be the average size of the pores or may be the maximum size of the pores.

With respect to the material of the porous member, one of the first and second porous members may be formed of one of organic, inorganic (ceramic), metal, and hybrid type porous materials, and the other one may be formed of one of organic, inorganic (ceramic), metal, and or hybrid type porous material different from the first material.

In terms of the shape of the porous member, the first and second porous members 1500 and 1600 may have different shapes.

By varying the arrangement, size, material, and shape of the pores of the first and second porous members 1500 and 1600 as described above, the transfer head 1000 has various functions and each of the first and second porous members 1500 and 1600 performs complementary functions.

The number of the porous members is not limited to two as in the case of the first and second porous members. As long as the respective porous members have mutually complementary functions, providing two or more porous members also falls into the seventh modification of the transfer head 1000.

Eighth Modification of the Transfer Head 1000

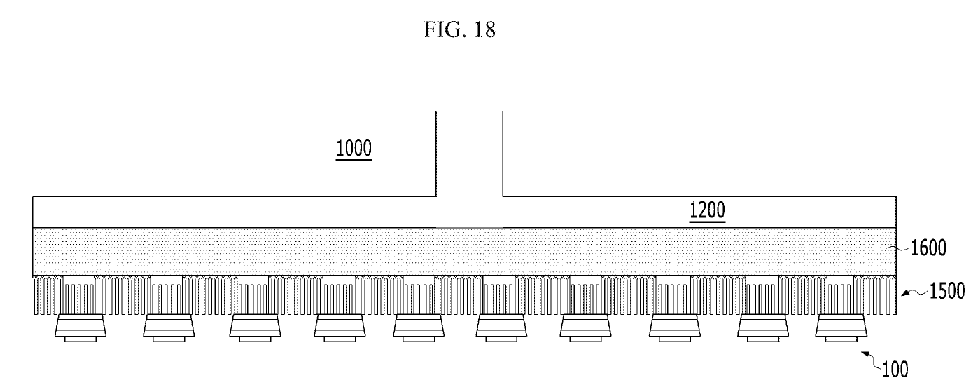

Hereinbelow, an eighth modification of the transfer head 1000 will be described with reference to FIG. 18.

FIG. 18 is a view illustrating a state in which an eighth modification of the transfer head grips the micro LEDs.

As illustrated in FIG. 18, the first porous member 1500 of the eighth modification of the transfer head 1000 is provided with the anodic oxide film 1300 having the pores formed by anodizing a metal.

The first porous member 1500 may be employed in the first to sixth modifications of the transfer head 1000.

The second porous member 1600 may be composed of a porous scaffold functioning to support the first porous member 1500.

A material of the second porous member 1600 is not limited as long as the second porous member 1600 functions to support the first porous member 1500. The second porous member 1600 may have the above-mentioned configuration of the porous member 1100 of the transfer head 1000 of the system 10 for transferring a micro LED according to the first embodiment of the present invention.

The second porous member 1600 may be composed of a rigid porous scaffold capable of preventing sagging at the center portion of the first porous member 1500. For example, the second porous member 1600 may be formed of a porous ceramic material.

Alternatively, the first porous member 1500 may be employed in first to sixth modifications of the transfer head 1000, and the second porous member 1600 may be composed of a porous buffer to buffer the contact between the first porous member 1500 and the micro LEDs 100.

A material of the second porous member 1600 is not limited as long as the second porous member 1600 functions to buffer the first porous member 1500. The second porous member 1600 may have the above-mentioned configuration of the porous member 1100 of the transfer head 1000 of the system 10 for transferring a micro LED according to the first embodiment of the present invention.

The second porous member 1600 may be composed of a soft porous buffer that helps to protect the micro LEDs 100 from damage, which may occur when the micro LEDs 100 and the first porous member 1500 are brought into contact with each other to grip the micro LED 100s by the vacuum-suction. For example, the second porous member 1600 may be composed of a porous elastic material such as a sponge or the like.

Ninth Modification of the Transfer Head 1000

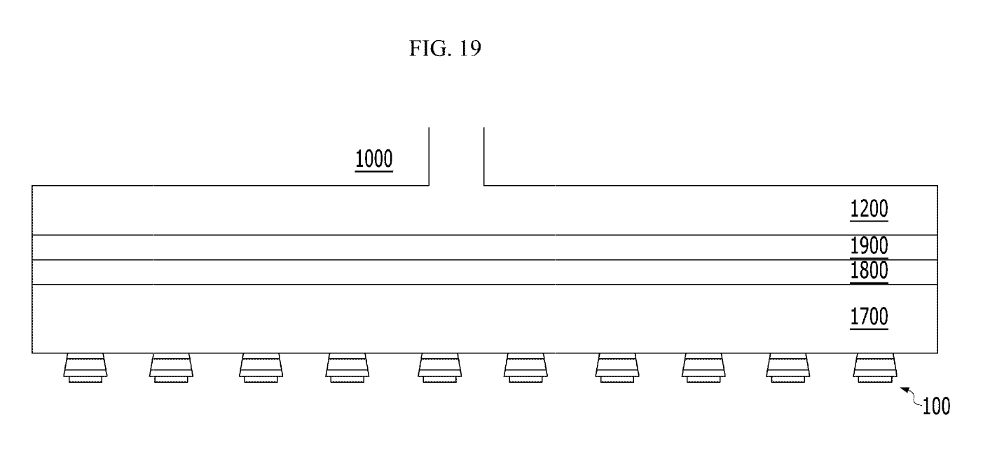

Hereinbelow, a ninth modification of the transfer head 1000 will be described with reference to FIG. 19.

FIG. 19 is a view illustrating a state in which a ninth modification of the transfer head grips the micro LEDs.

As illustrated in FIG. 19, the ninth modification of the transfer head 1000 is configured such that the above-described porous member 1100 of the transfer head 1000 of the system 10 for transferring a micro LED according to the first embodiment is configured to have three porous members including a first porous member 1700, a second porous member 1800, and a third porous member 1900.

The second porous member 1800 is provided on the first porous member 1700, and the third porous member 1900 is provided on the second porous member 1800. The first porous member 1700 functions to vacuum-suck the micro LEDs 100. At least one of the second porous member 1800 and the third porous member 1900 may be composed of a rigid porous scaffold, and the remaining one of the second porous member 1800 and the third porous member 1900 may be composed of a soft porous buffer.

With the above structure, it is possible to vacuum-suck the micro LEDs, prevent the sagging at the center portion of the first porous member 1700, and prevent damage to the micro LEDs 100.

Tenth Modification of the Transfer Head 1000

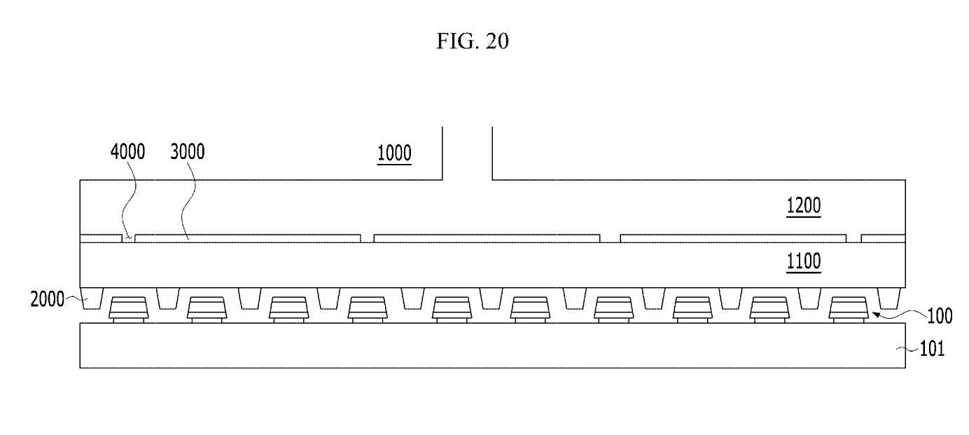

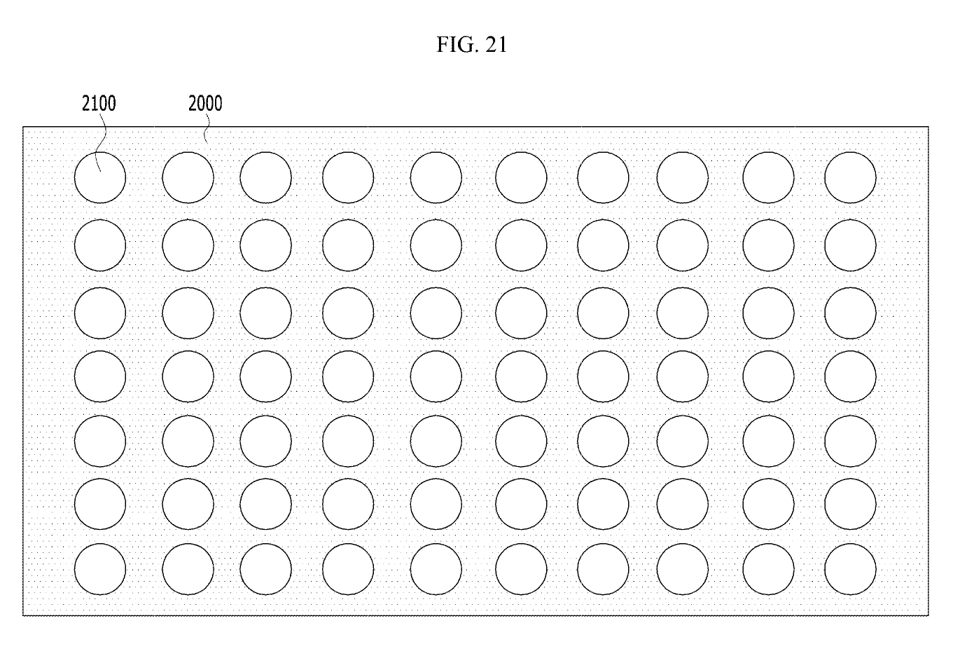

Hereinbelow, a tenth modification of the transfer head 1000 will be described with reference to FIGS. 20 and 21.

FIG. 20 is a view illustrating a state in which a tenth modification of the transfer head grips the micro LEDs; and FIG. 21 is a view illustrating various embodiments of a dam of the transfer head of FIG. 20.

As illustrated in FIG. 20, the tenth modification of the transfer head 1000 is configured such that a dam 2000 is provided at a lower portion of the porous member 1100 of the transfer head 1000 of the system 10 for transferring a micro LED according to the first embodiment.

A material of the dam 2000 may be formed of a photoresist (PR, including dry film PR) or a metal. The dam 2000 may be formed of any material that can be formed on a surface of the porous member 1100 with a predetermined height.

A cross-sectional shape of a protruding portion of the dam 2000 may be any protruding shape such as a quadrangle, a circle, and a triangle.

The cross-sectional shape of the protruding portion of the dam 2000 may be configured in consideration of the shape of the micro LEDs 100.

For example, in the case the micro LEDs 100 have a structure in which an upper portion thereof is wider than a lower portion thereof, it is advantageous in terms of prevention of interference between the dam 2000 and the micro LEDs 100 that the protruding portion of the dam 2000 has a structure in which a lower portion thereof has a narrower cross section than an upper portion thereof.

Referring to FIG. 20, the protruding portion of the dam 2000 has a cross section tapered downward.

When descending the transfer head 1000 to the suction position to grip the micro LEDs 100 positioned on the first substrate 101 by vacuum-suction, an error in a driving means of the transfer head 1000 may cause the contact between the porous member 1100 and the micro LEDs 100, leading to damage to the micro LEDs 100.

In order to prevent damage to the micro LEDs 100, it is preferable that the lower surface of the porous member 1100 and the upper surfaces of the micro LEDs 100 are spaced apart from each other at a position where the transfer head 1000 sucks the micro LEDs 100. However, when there is a gap between the lower surface of the porous member 1100 and the micro LEDs 100, a larger vacuum pressure is required compared with the case where the micro LEDs 100 and the porous member 1100 are in contact with each other.

However, the configuration of the dam 2000 of the tenth modification of the transfer head 1000 reduces the amount of air flowing into the suction region 1110 from the peripheral area. Thus, the porous member 1100 of the tenth modification can vacuum-suck the micro LEDs 100 by a smaller vacuum pressure compared with the configuration in which the dam 2000 is not provided.

There is a case that a length of the protruding portion of the dam 2000 is configured to be longer than the height of the micro LEDs 100. In this case, when descending the transfer head 1000 to the lowermost position, the dam 2000 may come into contact with the first substrate 101, but the lower surface of the porous member 1100 may be not in contact with the upper surfaces of the micro LEDs 100.

According to the configuration in which the dam 2000 come into contact with the first substrate 101 and the lower surface of the porous member 1100 is spaced from the upper surfaces of the micro LEDs 100, the dam 2000 more reliably blocks the inflow of air from the peripheral area to the suction region 1110 as compared with the configuration in which the porous member 1100 and the micro LEDs 100 are spaced apart from each other. Thus, the porous member 1100 having the dam 2000 can vacuum-suck the micro LEDs 100 easily.

In addition, even when air flow causes the adjacent micro LEDs 100 to move finely, it is possible to physically restrict the position of the micro LEDs 100 due to the dam 2000.

A shielding portion 3000 is provided on an upper surface of the porous member 1100 to configure a non-suction region. A region 4000 communicating with the suction chamber 1200 is provided between adjacent shielding portions 3000 to configure the suction region 1110.

The shielding portion is not limited in material, shape, and thickness as long as the shielding portion functions to close the pores exposed to the surface of the porous member 1100. Preferably, the shielding portion may be further provided and formed of a photoresist (PR, including dry film PR) or a metal. In the case the porous member 1100 is formed of an anodic oxide film, the shielding portion may be a barrier layer or a metal base material.

FIG. 21 is a bottom view of the porous member 1100 provided with the dam 2000.

As illustrated in FIG. 21, the dam 2000 is formed entirely except an opening 2100 which becomes the suction region 1110.

The opening 2100 of the dam 2000 may be configured at the same pitch distance as the arrangement of the micro LEDs 100 on the first substrate 101.

Openings 2100 of the dam 2000 may be arranged in an m by n matrix as illustrated in FIG. 21.

When pitch distances of the micro LEDs 100 on the first substrate 101 are P(n) in the column direction and P(m) in the row direction, pitch distances of the opening 2100 of the dam 2000 are P(n) in a column direction and P(m) in a row direction. In this case, the opening 2100 of the dam 2000 is in one-to-one correspondence with the micro LED 100 to be gripped.

In the case of the present invention, since the micro LED 100 has a circular cross-section, the opening 2100 is also formed in a circular shape as illustrated in FIG. 21. However, the shape of the opening 2100 may vary depending on the cross-sectional shape of the micro LED 100. For example, when the micro LED 100 has a rectangular cross-section, the opening 2100 may have a rectangular cross-section corresponding to the cross-sectional shape of the micro LED 100.

Eleventh Modification of the Transfer Head 1000

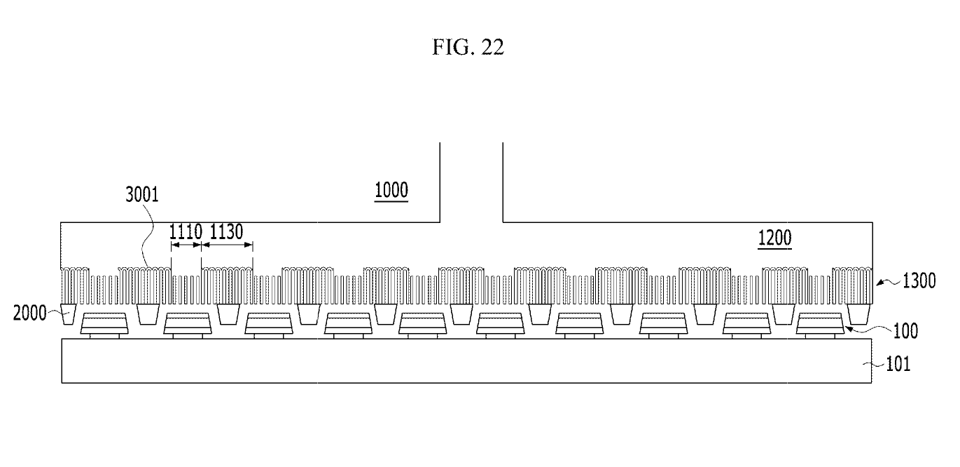

Hereinbelow, an eleventh modification of the transfer head 1000 will be described with reference to FIG. 22.

FIG. 22 is a view illustrating a state in which an eleventh modification of the transfer head grips the micro LEDs.

As illustrated in FIG. 22, the eleventh modification of the transfer head 1000 is configured such that the porous member 1100 of the transfer head 1000 of the system 10 for transferring a micro LED according to the first embodiment is embodied by the anodic oxide film 1300 having the pores formed by anodizing a metal.

Referring to FIG. 22, the dam 2000 is formed on the lower surface of the anodic oxide film 1300.

The anodic oxide film 1300 includes a portion in which a surface of a barrier layer 3001 provided on the anodic oxide film 1300 is removed such that the suction region 1110 is formed and a portion in which the surface of the barrier layer 3001 is not removed such that the non-suction region 1130 is formed.

In this case, the barrier layer 3001 functions as the shielding portion 3000 illustrated in FIG. 20, and a region where the barrier layer 3001 is not provided functions as the region 4000 communicating with the suction chamber 1200 illustrated in FIG. 20.

Twelfth and Thirteenth Modifications of the Transfer Head 1000

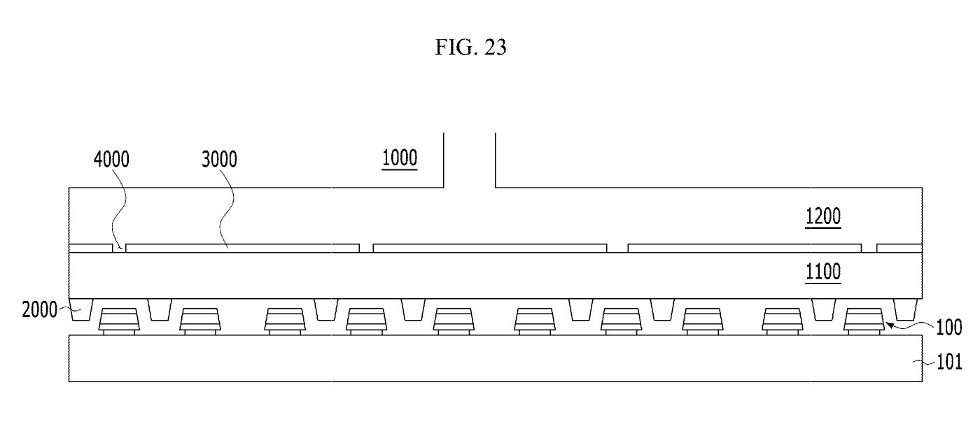

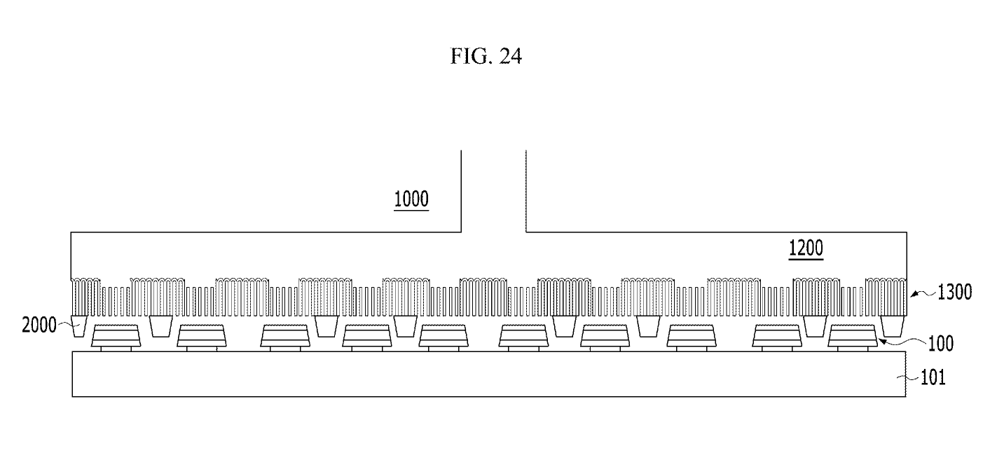

Hereinbelow, twelfth and thirteenth modifications of the transfer head 1000 will be described with reference to FIGS. 23 and 24.

FIG. 23 is a view illustrating a state in which a twelfth modification of the transfer head grips the micro LEDs; and FIG. 24 is a view illustrating a state in which a thirteenth modification of the transfer head grips the micro LEDs.

As illustrated in FIGS. 23 and 24, the dam 2000 is provided only around the micro LEDs 100 to be gripped in the suction region 1110.

As illustrated in FIGS. 23 and 24, the micro LEDs 100 to be gripped on the first substrate 101 are the micro LEDs 100 at the 1st, 4th, 7th, and 10th positions with reference to the left side of the drawing. The dam 2000 functions to block the inflow of air from the peripheral area to each suction region 1110 when the transfer head 1000 grips the micro LEDs 100 at the 1st, 4th, 7th, and 10th positions by vacuum-suction.

Here, the dam 2000 provided on the lower surface of the anodic oxide film 1300 may have the shape of the dam 2000 of FIG. 21.

As described above, the present invention has been described with reference to the preferred embodiments. However, those skilled in the art will appreciate that various modifications, additions and substitutions are possible, without departing from the scope and spirit of the invention as disclosed in the accompanying claims.

1. A system having a transfer head for transferring a micro LED, the system comprising:
a first substrate provided in a transfer chamber and on which a micro LED is formed;
a second substrate provided in the transfer chamber and on which the micro LED is mounted;
a transfer head provided between the first substrate and the second substrate in the transfer chamber and transferring the micro LED; and
a spraying unit provided in the transfer chamber spraying ionized gas.

2. The system of claim 1, wherein the spraying unit is configured as a spraying unit for a transfer chamber to replace the atmosphere in the transfer chamber with the ionized gas.

3. The system of claim 1, wherein the spraying unit is configured as a spraying unit for the first substrate to spray the ionized gas on an upper surface of the first substrate.

4. The system of claim 1, wherein the spraying unit is configured as a spraying unit for the second substrate to spray the ionized gas on an upper surface of the second substrate.

5. The system of claim 1, wherein the spraying unit is configured as a spraying unit for the transfer head to spray the ionized gas on a lower surface of the micro LED gripped by the transfer head.
